(19) United States
(12) Patent Application Publication
(10) Pub. No.: US 2026/0247766 A1
(43) Pub. Date: Aug. 20, 2026

(54) DISPLAY DEVICE AND ELECTRONIC DEVICE

(71) Applicant: Samsung Display Co., Ltd., Yongin-si (KR)

(72) Inventors: Ji Wook MOON, Yongin-si (KR); Min Woo KIM, Yongin-si (KR); Young Kyo SEO, Yongin-si (KR); So Yeon YOON, Yongin-si (KR); Gwang Geun LEE, Yongin-si (KR); Ju Yon LEE, Yongin-si (KR)

(21) Appl. No.: 19/391,278

(22) Filed: Nov. 17, 2025

(30) Foreign Application Priority Data
Feb. 18, 2025 (KR) 10-2025-0020685

(51) Int. Cl. H10H 20/857; H10H 20/812; H10H 20/813; H10H 20/831; H10H 20/833; H10H 20/84

(52) U.S. Cl. CPC H10H 20/857; H10H 20/8131; H10H 20/8312; H10H 20/8314; H10H 20/833; H10H 20/84; H10H 20/812

(57) ABSTRACT

A display device includes: a substrate; pixel electrodes and a common electrode located on the substrate; and a light emitting element located on the pixel electrodes and the common electrode, wherein the light emitting element includes: a semiconductor stack having a structure in which light emitting units configured to emit light of different colors are stacked; a passivation film located on a side surface of the semiconductor stack; and at least one side electrode located on a side surface of the passivation film and electrically connected to the semiconductor stack on the side surface of the semiconductor stack.

### CROSS-REFERENCE TO RELATED APPLICATION

This application claims priority to and the benefit of Korean Patent Application No. 10-2025-0020685, filed on Feb. 18, 2025, in the Korean Intellectual Property Office, the entire disclosure of which is incorporated by reference herein.

### BACKGROUND

### 1. Field

Embodiments of the present disclosure relate to a display device and an electronic device, and more particularly, to a display device and an electronic device including a light emitting element.

### 2. Description of the Related Art

With the advance of information-oriented society, more and more demands are placed on display devices and electronic devices capable of displaying images in various ways. Accordingly, various types of display devices and electronic devices including pixels for displaying images are being developed. A display device may be provided alone, or may be included in an electronic device and used as a display screen of the electronic device.

### SUMMARY

Aspects and features of embodiments of the present disclosure provide a display device and an electronic device including a light emitting element with improved luminous efficiency.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, there is provided a display device includes: a substrate; pixel electrodes and a common electrode located on the substrate; and a light emitting element located on the pixel electrodes and the common electrode, wherein the light emitting element includes: a semiconductor stack having a structure in which light emitting units configured to emit light of different colors are stacked; a passivation film located on a side surface of the semiconductor stack; and at least one side electrode located on a side surface of the passivation film and electrically connected to the semiconductor stack on the side surface of the semiconductor stack.

In one or more embodiments, the light emitting element further includes at least one bottom electrode located on a bottom surface of the semiconductor stack and electrically connected to the semiconductor stack.

In one or more embodiments, each of the light emitting units includes an active layer, and a first conductivity type semiconductor layer and a second conductivity type semiconductor layer located on different surfaces of the active layer, and wherein the at least one bottom electrode includes a first electrode located on a part of the bottom surface of the semiconductor stack and electrically connected to second conductivity type semiconductor layers of the light emitting units, wherein the first electrode penetrates a part of the semiconductor stack.

In one or more embodiments the first electrode is bonded onto the common electrode.

In one or more embodiments, the at least one bottom electrode further includes a second electrode located on another part of the bottom surface of the semiconductor stack and electrically connected to the first conductivity type semiconductor layer of one of the light emitting units.

In one or more embodiments, the second electrode is bonded onto one of the pixel electrodes.

In one or more embodiments, each of the light emitting units includes an active layer, and a first conductivity type semiconductor layer and a second conductivity type semiconductor layer located on different surfaces of the active layer, and wherein the at least one side electrode includes a third electrode located on a part of the side surface of the semiconductor stack and in contact with a side surface of the first conductivity type semiconductor layer of one of the light emitting units, wherein the third electrode penetrates the passivation film.

In one or more embodiments, the third electrode is located on one of the pixel electrodes.

In one or more embodiments, the display device further includes a connection electrode located on the third electrode and the one of the pixel electrodes, the connection electrode electrically connecting the third electrode to the one of the pixel electrodes.

In one or more embodiments, the at least one side electrode includes a transparent conductive material.

In one or more embodiments, the light emitting units include: a first light emitting unit including a first active layer configured to emit light of a first color, and a first semiconductor layer and a second semiconductor layer located on different surfaces of the first active layer; a second light emitting unit including a second active layer configured to emit light of a second color, and a third semiconductor layer and a fourth semiconductor layer located on different surfaces of the second active layer; and a third light emitting unit including a third active layer configured to emit light of a third color, and a fifth semiconductor layer and a sixth semiconductor layer located on different surfaces of the third active layer.

In one or more embodiments, the pixel electrodes include a first pixel electrode electrically connected to the first light emitting unit, a second pixel electrode electrically connected to the second light emitting unit, and a third pixel electrode electrically connected to the third light emitting unit, and wherein the light emitting element includes a first electrode electrically connected to the common electrode, a second electrode electrically connected to the first pixel electrode, a third electrode electrically connected to the second pixel electrode, and a fourth electrode electrically connected to the third pixel electrode.

In one or more embodiments, the at least one side electrode includes the third electrode and the fourth electrode, wherein the third electrode is located on one side surface of the passivation film overlapping the second pixel electrode, and is in contact with a side surface of the third semiconductor layer, wherein the third electrode penetrates the passivation film, and wherein the fourth electrode is located on one side surface of the passivation film overlapping the third pixel electrode, and is in contact with a side surface of the fifth semiconductor layer, wherein the fourth electrode penetrates the passivation film.

In one or more embodiments, the display device further includes: a first connection electrode located on the third electrode and the second pixel electrode, and electrically connecting the third electrode to the second pixel electrode; and a second connection electrode located on the fourth electrode and the third pixel electrode, and electrically connecting the fourth electrode to the third pixel electrode.

In one or more embodiments, the at least one side electrode further includes at least one of the first electrode or the second electrode, and wherein the display device further including at least one of a third connection electrode electrically connecting the first electrode to the common electrode, or a fourth connection electrode electrically connecting the second electrode to the first pixel electrode.

In one or more embodiments, the first electrode is located on one side surface of the passivation film overlapping the common electrode, and is in contact with a side surface of each of the second semiconductor layer, the fourth semiconductor layer, and the sixth semiconductor layer, wherein the first electrode penetrates the passivation film, and wherein the second electrode is located on one side surface of the passivation film overlapping the first pixel electrode, and is in contact with a side surface of the first semiconductor layer, wherein the second electrode penetrates the passivation film.

In one or more embodiments, the light emitting element further includes at least one bottom electrode located on a bottom surface of the semiconductor stack, and wherein the at least one bottom electrode includes at least one of the first electrode or the second electrode.

In one or more embodiments, the first electrode is located on a part of the bottom surface of the semiconductor stack and a top surface of the common electrode and bonded to the common electrode, wherein the first electrode is electrically connected to the second semiconductor layer, the fourth semiconductor layer, and the sixth semiconductor layer and penetrates a part of the semiconductor stack, and wherein the second electrode is located on another part of the bottom surface of the semiconductor stack and a top surface of the first pixel electrode and bonded to the first pixel electrode, the second electrode being electrically connected to the first semiconductor layer.

In one or more embodiments, an electronic device includes: a display module including a display panel; and a processor configured to transmit an image data signal to the display module, wherein the display panel includes: a substrate; pixel electrodes and a common electrode located on the substrate; a light emitting element located on the pixel electrodes and the common electrode, the light emitting element including a semiconductor stack having a structure in which light emitting units configured to emit light of different colors are stacked, a passivation film located on a side surface of the semiconductor stack, and a side electrode located on a side surface of the passivation film and electrically connected to the semiconductor stack on the side surface of the semiconductor stack; and a connection electrode located on one of the pixel electrodes or the common electrode and the side electrode and electrically connecting the one of the pixel electrodes or the common electrode to the side electrode.

In one or more embodiments, the light emitting element further includes a bottom electrode located on a bottom surface of the semiconductor stack and electrically connected to the semiconductor stack, and wherein the bottom electrode is bonded onto another one of the pixel electrodes or the common electrode.

The display device and the electronic device according to one or more embodiments may include a light emitting element. The light emitting element according to one or more embodiments may include a semiconductor stack including light emitting units configured to emit light of different colors, a passivation film located on the side surface of the semiconductor stack, and a side electrode located on the side surface of the passivation film and electrically connected to the semiconductor stack on the side surface of the semiconductor stack.

According to one or more embodiments, the loss of the emission area due to the electrodes connected to the semiconductor stack may be reduced or minimized, and the luminous efficiency of the light emitting element may be improved. Accordingly, the light efficiency of the display device and the electronic device including the light emitting element may be improved. In addition, according to one or more embodiments, the light emitting elements of sub-pixels forming a pixel are integrated into one light emitting element, so that the size of the pixel may be reduced. Accordingly, a high-resolution display device and electronic device may be manufactured.

In one or more embodiments, the light emitting element may further include a bottom electrode located on the bottom surface of the semiconductor stack. In a display device and an electronic device including a light emitting element according to one or more embodiments, the light emitting element may be more stably located on the pixel electrode layer of the display device and the electronic device. Accordingly, the reliability of the display device and the electronic device may be improved.

However, effects, aspects, and features of the embodiments of the present disclosure are not limited to those discussed above and various other effects, aspects, and features are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to one or more embodiments;

FIG. 2 is a layout view illustrating a display device according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is a plan view illustrating a display area of a display panel according to one or more embodiments;

FIG. 6-10 are plan views showing a light emitting element according to one or more embodiments;

FIG. 11 is a cross-sectional view illustrating a display area of a display panel according to one or more embodiments;

FIG. 12 is a cross-sectional view illustrating a display area of a display panel according to one or more embodiments;

FIG. 13 is a cross-sectional view showing an area A1 of FIG. 11 in detail;

FIG. 14 is a cross-sectional view illustrating a display area of a display panel according to one or more embodiments;

FIG. 15 is a cross-sectional view illustrating a display area of a display panel according to one or more embodiments;

FIG. 16 is a plan view illustrating a display area of a display panel according to one or more embodiments;

FIG. 17 is a plan view illustrating a display area of a display panel according to one or more embodiments;

FIG. 18-21 are plan views showing a light emitting element according to one embodiment;

FIG. 22 is a cross-sectional view illustrating a display area of a display panel according to one or more embodiments;

FIG. 23 is a block diagram of an electronic device according to one or more embodiments; and

FIG. 24 is schematic views of electronic devices according to various embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

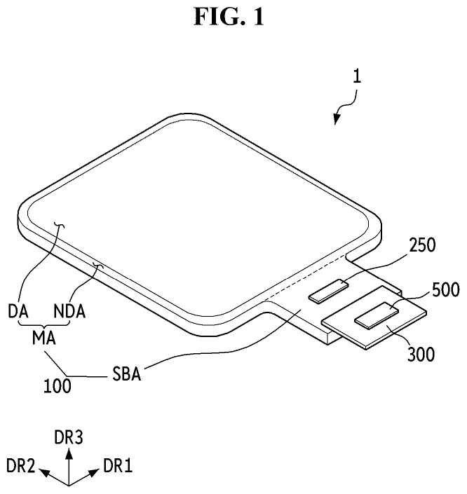

FIG. 1 is a perspective view illustrating a display device according to one or more embodiments.

Referring to FIG. 1, a display device 1 may be a device capable of providing an image, such as a moving image and/or a still image. For example, the display device 1 may be a device that includes a display module including a display panel 100 and thus may display an image. As an example, the display device 1 may refer to all electronic devices that provide a display screen on which an image may be displayed or include a display module for displaying an image.

The display device 1 may be provided alone, or may be included in an electronic device providing a display screen to form the display screen of the electronic device. For example, the display device 1 may be included in various electronic devices such as televisions, laptop computers, monitors, billboards and the Internet of Things (IOT) as well as portable electronic devices such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs), and used as a display screen. In addition, the display device 1 may be included in other electronic devices such as a virtual reality (VR) device, an augmented reality (AR) device, and/or the like and used to display an image in the electronic device. In one or more embodiments, the electronic device including the display device 1 may further include a display device housing in which the display device 1 is accommodated and/or a case or cover for protecting the display device 1.

In FIG. 1, a display module, which is a main component of the display device 1, is illustrated. In one or more embodiments, the display device 1 (or an electronic device including a display module) may further include an additional component. For example, the display device 1 may further include a housing or a casing that accommodates the display module of FIG. 1.

In one or more embodiments, the display device 1 may be a light emitting display device such as an organic light emitting display using an organic light emitting diode, a quantum dot light emitting display including a quantum dot light emitting layer, an inorganic light emitting display including an inorganic semiconductor, and an ultra-small light emitting display using an ultra-small light emitting diode (for example, a micro light emitting diode (micro LED) or a nano light emitting diode (nano LED)). Hereinafter, as an example of the display device 1 to which embodiments may be applied, a micro or nano light emitting display including a micro or nano light emitting diode will be disclosed. However, the present disclosure is not limited thereto. For example, the type of light emitting element included in the display device 1 is not limited to an ultra-small light emitting diode, and the display device 1 may include light emitting elements of other types and/or sizes.

The display device 1 may include a display panel 100, a display driving circuit 250, a circuit board 300, and a power supply unit 500 (also referred to as “power supply circuit”).

The display panel 100 may, in a plan view, may be formed in a rectangular shape having short sides in a first direction DR1 and long sides in a second direction DR2 crossing the first direction DR1. The corner where the sides in the first direction DR1 and the sides in the second direction DR2 meet may be formed in a rounded or angled shape. The planar shape of the display panel 100 is not limited to the rectangular shape, and may be formed in another polygonal shape, a circular shape or an elliptical shape. The display panel 100 may be formed to be substantially flat, but is not limited thereto. The display panel 100 may be formed to be rigid as a whole, or may be formed to be flexible so that it can be curved, warped, bent, folded, and/or rolled in at least one part.

The display panel 100 may include a main region MA and a sub-region SBA.

The main region MA may include a display area DA for displaying an image and a non-display area NDA that is a peripheral area of the display area DA. The display area DA may include pixels for displaying an image. Each of the pixels may include a plurality of sub-pixels. For example, each of the pixels may include a first sub-pixel that emits light of a first color, a second sub-pixel that emits light of a second color, and a third sub-pixel that emits light of a third color, but the present disclosure is not limited thereto.

The sub-region SBA may protrude from one side of the main region MA in the second direction DR2. Although it is shown as an example in FIG. 1 that the sub-region SBA is unfolded, the sub-region SBA may be bent and, in this case, arranged on the bottom surface of the display panel 100. In the case where the sub-region SBA is bent, it may overlap the main region MA in a third direction DR3 that is a thickness direction of the display panel 100. The display driving circuit 250 may be arranged in the sub-region SBA.

The display driving circuit 250 may generate signals and voltages for driving the display panel 100. The display driving circuit 250 may be formed as an integrated circuit (IC) and attached onto the display panel 100 by a chip on glass (COG) method, a chip on plastic (COP) method, or an ultrasonic bonding method, but the present disclosure is not limited thereto. For example, the display driving circuit 250 may be attached onto the circuit board 300 by a chip on film (COF) method.

The circuit board 300 may be attached to one end of the sub-region SBA. In the case where the sub-region SBA is omitted, the circuit board 300 may be attached to one end (for example, one end of the non-display area NDA of the main region MA. Thus, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film.

The power supply unit 500 may generate a plurality of panel driving voltages according to a power voltage supplied from the outside. The power supply unit 500 may be formed as an integrated circuit (IC) and attached to the circuit board 300 by a COF method.

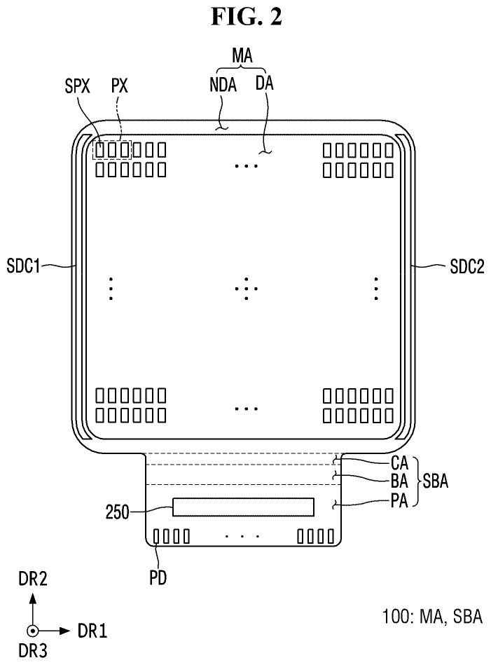

FIG. 2 is a layout view illustrating a display device according to one or more embodiments. It is shown as an example in FIG. 2 that the sub-region SBA is unfolded without being bent.

Referring to FIG. 2, the display panel 100 may include the main region MA and the sub-region SBA.

The main region MA may include the display area DA for displaying an image and the non-display area NDA that is a peripheral area of the display area DA. The display area DA may occupy most of the main region MA. The display area DA may be located at the center of the main region MA.

The display area DA may include pixels PX for displaying an image, and each of the pixels PX may include a plurality of sub-pixels SPX. The pixel PX may be defined as a minimum unit sub-pixel group capable of expressing a white gray level.

The non-display area NDA may be located adjacent to the display area DA. The non-display area NDA may be an area outside the display area DA. The non-display area NDA may be around (e.g., may surround) the display area DA. The non-display area NDA may be an edge area of the display panel 100.

A first scan driver SDC1 and a second scan driver SDC2 may be located in the non-display area NDA. The first scan driver SDC1 may be located at one side (for example, left side) of the display panel 100, and the second scan driver SDC2 may be located at the other side (for example, right side) of the display panel 100, but the present disclosure is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive scan control signals inputted from the display driving circuit 250, generate scan signals in response to the scan control signals, and output the generated scan signals to scan lines.

The sub-region SBA may protrude from one side of the main region MA in the second direction DR2. The length of the sub-region SBA in the second direction DR2 may be less than the length of the main region MA in the second direction DR2. The length of the sub-region SBA in the first direction DR1 may be substantially equal to or less than the length of the main region MA in the first direction DR1. The sub-region SBA may be foldable to be located under the display panel 100. In this case, the sub-region SBA may overlap the main region MA in the third direction DR3.

The sub-region SBA may include a connection area CA, a pad area PA, and a bending area BA.

The connection area CA is an area protruding from one side of the main region MA in the second direction DR2. One side of the connection area CA may be in contact with the non-display area NDA of the main region MA, and the other side of the connection area CA may be in contact with the bending area BA.

The pad area PA is an area on which pads PD and the display driving circuit 250 are arranged. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is an area being bent. When the bending area BA is bent, the pad area PA may be located under the connection area CA and the main region MA. The bending area BA may be located between the connection area CA and the pad area PA. One side of the bending area BA may be in contact with the connection area CA, and the other side of the bending area BA may be in contact with the pad area PA.

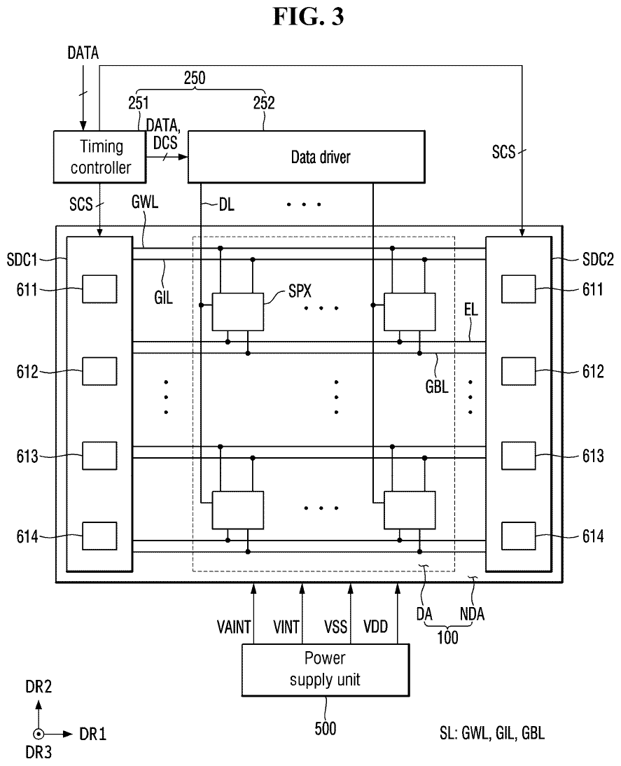

FIG. 3 is a block diagram illustrating a display device according to one or more embodiments.

Referring to FIG. 3 in addition to FIGS. 1 and 2, the display area DA may include pixels PX, scan lines SL, emission control lines EL, and data lines DL.

The pixels PX may be arranged in a matrix form or the like. For example, the pixels PX may be arranged in a matrix form along the first direction DR1 and the second direction DR2, but the present disclosure is not limited thereto. For example, the pixels PX may be arranged along rows and columns of a matrix along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. In one or more embodiments, the scan lines SL may include write scan lines GWL, initialization scan lines GIL, and bias scan lines GBL.

Each of the plurality of sub-pixels SPX included in each of the pixels PX may be connected to one write scan line GWL from among the write scan lines GWL, one initialization scan line GIL from among the initialization scan lines GIL, one bias scan line GBL from among the bias scan lines GBL, one emission control line EL from among the emission control lines EL, and one data line DL from among the data lines DL. In describing the embodiments, the term “connection” may include direct connection or indirect connection, and may include the meaning of electrical and/or physical connection. Each of the plurality of sub-pixels SPX may receive the data voltage of the data line DL according to the write scan signal of the write scan line GWL, and may cause a light emitting element to emit light according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, an initialization scan signal output unit 612, a bias scan signal output unit 613, and an emission control signal output unit 614. Each of the write scan signal output unit 611, the initialization scan signal output unit 612, the bias scan signal output unit 613, and the emission control signal output unit 614 may receive a scan timing control signal SCS from a timing controller 251 (also referred to as “timing control circuit”).

The write scan signal output unit 611 may generate write scan signals according to the scan timing control signal SCS of the timing controller 251 and output them sequentially to the write scan lines GWL.

The initialization scan signal output unit 612 may generate initialization scan signals in response to the scan timing control signal SCS and sequentially output them to the initialization scan lines GIL.

The bias scan signal output unit 613 may generate bias scan signals according to the scan timing control signal SCS and output them sequentially to the bias scan lines GBL.

The emission control signal output unit 614 may generate emission control signals according to the scan timing control signal SCS and sequentially output them to the emission control lines EL.

The display driving circuit 250 includes the timing controller 251 and a data driver 252 (also referred to as “data driving circuit”).

The data driver 252 may receive the digital video data DATA and the data timing control signal DCS from the timing controller 251. The data driver 252 converts the digital video data DATA into analog data voltages in response to the data timing control signal DCS, and outputs them to the data lines DL. In this case, the sub-pixels SPX may be selected by the write scan signal of the first scan driver SDC1 and the second scan driver SDC2, and data voltages may be supplied to the selected sub-pixels SPX.

The timing controller 251 may receive digital video data DATA and timing signals from the outside. The timing controller 251 may generate the scan timing control signal SCS and the data timing control signal DCS for controlling the display panel 100 in response to the timing signals. The timing control circuit 400 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power voltage supplied from the outside. For example, the power supply unit 500 may generate a first driving voltage VDD, a second driving voltage VSS, a third driving voltage VINT, and a fourth driving voltage VAINT and supply them to the display panel 100.

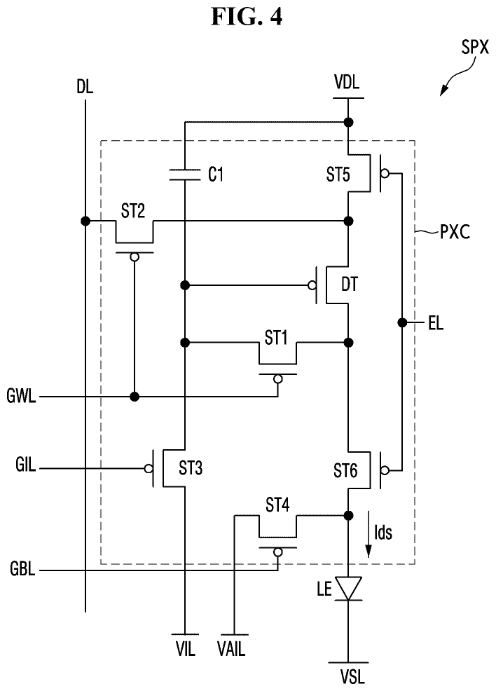

FIG. 4 is an equivalent circuit diagram illustrating a sub-pixel according to one or more embodiments.

Referring to FIG. 4 in addition to FIG. 3, the sub-pixel SPX according to one or more embodiments may be connected to the scan lines SL (see FIG. 3), the emission control line EL, and the data line DL. For example, the sub-pixel SPX may be connected to the write scan line GWL, the initialization scan line GIL, the bias scan line GBL, the emission control line EL, and the data line DL.

The sub-pixel SPX according to one or more embodiments may include a light emitting element LE and a pixel circuit PXC electrically connected to the light emitting element LE. The pixel circuit PXC may include circuit elements for driving the light emitting element LE. In one or more embodiments, each pixel PX may include a first sub-pixel, a second sub-pixel, and a third sub-pixel, and the first sub-pixel, the second sub-pixel, and the third sub-pixel may each include the pixel circuit PXC. In one or more embodiments, equivalent circuit diagrams of the first sub-pixel, the second sub-pixel, and the third sub-pixel may be the same.

The pixel circuit PXC may include the driving transistor DT, the switch elements, and a capacitor C1. In one or more embodiments, the switch elements may include first to sixth transistors ST1, ST2, ST3, ST4, ST5, and ST6.

The driving transistor DT includes a gate electrode, a first electrode, and a second electrode. The driving transistor DT controls the driving current Ids flowing between the first electrode and the second electrode according to a data voltage applied to the gate electrode of the driving transistor DT.

The light emitting element LE may be electrically connected to the driving transistor DT, and may emit light with a luminance corresponding to the driving current Ids. In one or more embodiments, the anode electrode of the light emitting element LE may be connected to the first electrode of the fourth transistor ST4 and the second electrode of the sixth transistor ST6, and the cathode electrode of the light emitting element LE may be connected to a second power line VSL to which a second driving voltage VSS (see FIG. 3) is applied. In one or more embodiments, the light emitting element LE may be a micro light emitting diode.

The capacitor C1 is formed between the gate electrode of the driving transistor DT and a first power line VDL to which a first driving voltage VDD (see FIG. 3) is applied. The first driving voltage VDD may be a voltage of a level higher than that of the second driving voltage VSS. One electrode of the capacitor C1 may be connected to the gate electrode of the driving transistor DT, and the other electrode thereof may be connected to the first power line VDL.

In one or more embodiments, as shown in FIG. 4, the first to sixth transistors ST1 to ST6, and the driving transistor DT may all be formed as p-type metal oxide semiconductor field effect transistors (MOSFETs) as shown in FIG. 4. The active layer of each of the driving transistor DT and the first to sixth transistors ST1 to ST6 may include polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1 to ST6 are formed as p-type MOSFETs, they may be turned on when a scan signal and an emission control signal of a gate low voltage are applied to the initialization scan line GIL, and the write scan line GWL, the bias scan line GBL, and the emission line EL. One electrode of the third transistor ST3 may be connected to a first initialization voltage line VIL to which the third driving voltage VINT (see FIG. 3) is applied, and one electrode of the fourth transistor ST4 may be connected to a second initialization voltage line VAIL to which the fourth driving voltage VAINT (see FIG. 3) is applied. The third driving voltage VINT and the fourth driving voltage VAINT may be different voltages. Further, the third driving voltage VINT and the fourth driving voltage VAINT may be voltages of a level lower than that of the first driving voltage VDD and a level higher than that of the second driving voltage VSS.

Alternatively, the driving transistor DT, the second transistor ST2, the fourth transistor ST4, the fifth transistor ST5, and the sixth transistor ST6 may be configured as p-type metal oxide semiconductor field effect transistors (MOSFETs), and the first transistor ST1 and the third transistor ST3 may be configured as n-type MOSFETs. In this case, an active layer of each of the driving transistor DT, the second transistor ST2, the fourth transistor ST4, the fifth transistor ST5 and the sixth transistor ST6 configured as the p-type MOSFETs may include polysilicon, whereas an active layer of each of the first transistor ST1 and the third transistor ST3 configured as the n-type MOSFETs may include an oxide semiconductor. In addition, because the first transistor ST1 and the third transistor ST3 are formed as n-type MOSFETs, the first transistor ST1 may be turned on when the scan signal of a gate high voltage is applied, and the third transistor ST3 may be turned on when the initialization scan signal of a gate high voltage is applied. In contrast, because the second transistor ST2, the fourth transistor ST4, the fifth transistor ST5, and the sixth transistor ST6 are configured as the p-type MOSFETs, they may be turned on when an emission control signal and a scan signal of a gate low voltage are applied.

Alternatively, when the fourth transistor ST4 is formed as an n-type MOSFET, and the other transistors DT, ST1, ST2, ST3, ST5, and ST6 are formed as p-type MOSFETs, the active layer of the fourth transistor ST4 may include an oxide semiconductor, and the active layer of each of the other transistors DT, ST1, ST2, ST3, ST5, and ST6 may include polysilicon. Further, the fourth transistor ST4 may be turned on when a scan signal of a gate high voltage is applied, whereas the other transistors DT, ST1, ST2, ST3, ST5, and ST6 may be turned on when an emission control signal and a scan signal of a gate low voltage are applied.

Alternatively, the first to sixth transistors ST1, ST2, ST3, ST4, ST5, and ST6, and the driving transistor DT may all be formed as n-type MOSFETs. In this case, the active layer of each of the driving transistor DT and the first to sixth transistors ST1, ST2, ST3, ST4, ST5, and ST6 may include an oxide semiconductor, and may be turned on when an emission control signal and a scan signal of a gate high voltage are applied.

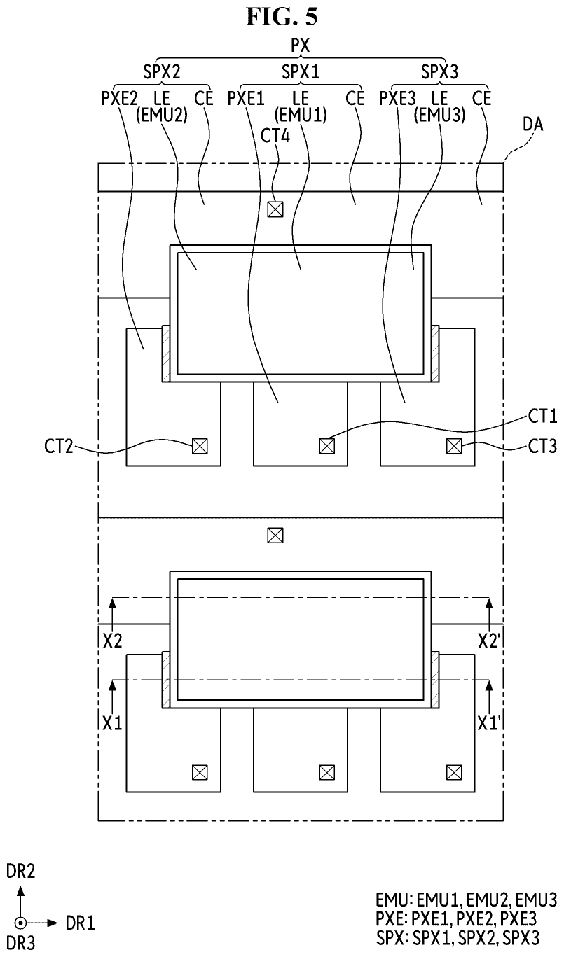

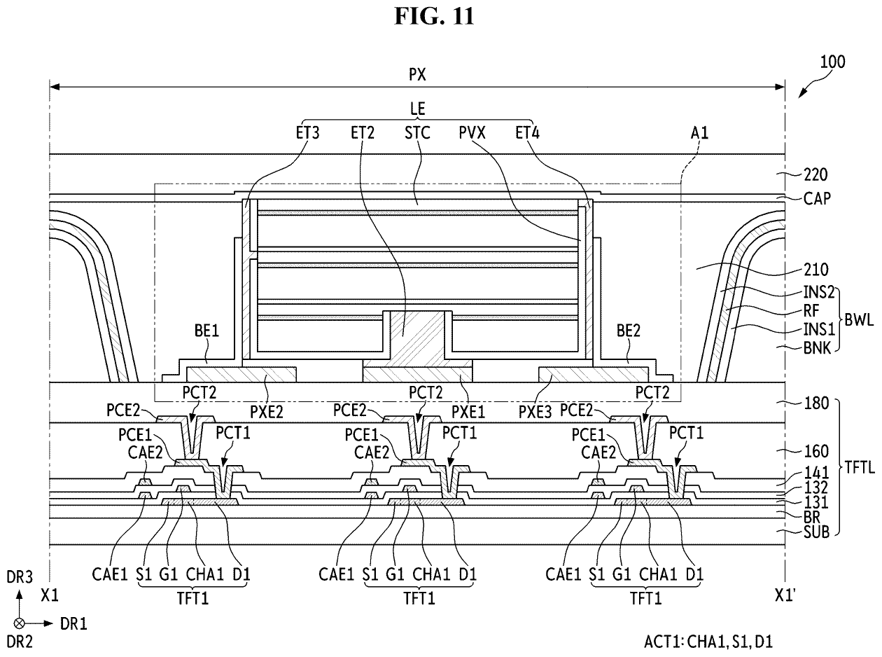

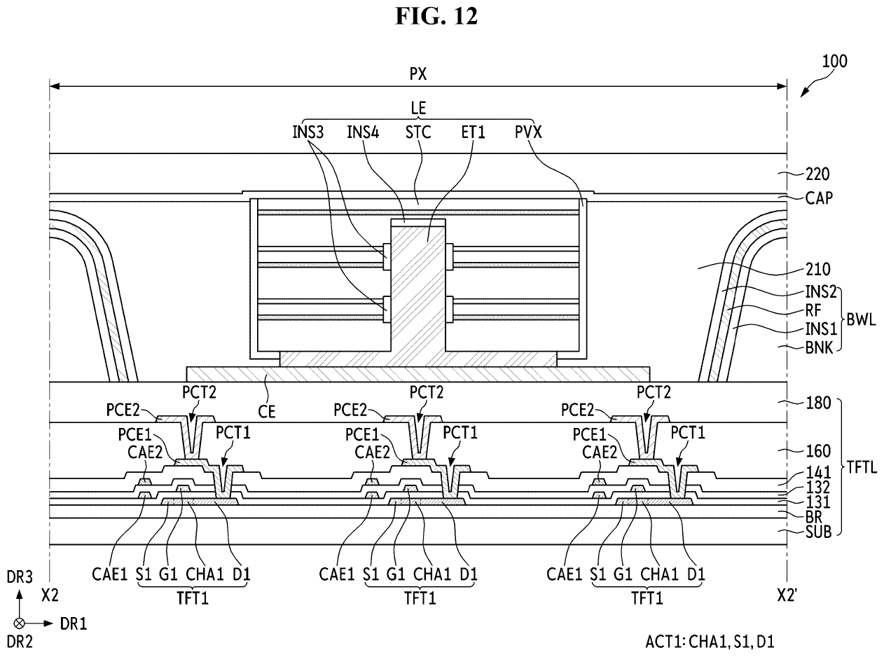

FIG. 5 is a plan view illustrating a display area of a display panel according to one or more embodiments. For example, FIG. 5 shows a part of the display area DA including two pixels PX sequentially arranged along the second direction DR2. FIG. 5 shows an embodiment of a layout structure of a light emitting element layer including the light emitting elements LE of the pixels PX from among elements included in the display panel 100 (see FIG. 1-3). The display panel 100 may further include a backplane layer (for example, a thin film transistor layer TFTL of FIGS. 11 and 12) including circuit elements (for example, transistors and a capacitor C1 of FIG. 4) electrically connected to the light emitting elements LE of the pixels PX.

Referring to FIG. 5, each of the pixels PX may include a plurality of pixel electrodes PXE, at least one common electrode CE, and at least one light emitting element LE. For example, each pixel PX may include a first pixel electrode PXE1, a second pixel electrode PXE2, a third pixel electrode PXE3, the common electrode CE, and the light emitting element LE.

The first pixel electrode PXE1 may be the pixel electrode PXE of the first sub-pixel SPX1. The second pixel electrode PXE2 may be the pixel electrode PXE of the second sub-pixel SPX2. The third pixel electrode PXE3 may be the pixel electrode PXE of the third sub-pixel SPX3.

In one or more embodiments, the pixel PX may include a single common electrode CE shared by the sub-pixels SPX. For example, the common electrode CE may extend in the first direction DR1 in each pixel row (or horizontal line) of the display area DA, and the sub-pixels SPX of the pixels PX located on the corresponding pixel row may share one common electrode CE. However, the present disclosure is not limited thereto. For example, the pixel PX may include a plurality of common electrodes CE that are separated into individual patterns and located in the respective sub-pixels SPX.

The pixel electrodes PXE and the common electrode CE may be located to be spaced (e.g., spaced apart) from each other in each pixel area. For example, the pixel electrodes PXE may be located to be spaced (e.g., spaced apart) from each other in the first direction DR1, and the common electrode CE may be located to be spaced (e.g., spaced apart) from the pixel electrodes PXE in the second direction DR2. The arrangement shape, position, and/or number of the pixel electrodes PXE and the common electrode CE may be variously changed according to embodiments.

In one or more embodiments, the first pixel electrode PXE1 may be located between the second pixel electrode PXE2 and the third pixel electrode PXE3, but the arrangement order or positions of the first pixel electrode PXE1, the second pixel electrode PXE2, and the third pixel electrode PXE3 may be changed. The first pixel electrode PXE1, the second pixel electrode PXE2, and the third pixel electrode PXE3 may face different parts of the common electrode CE in the second direction DR2.

The first pixel electrode PXE1 may be electrically connected to the circuit element included in the first sub-pixel SPX1. For example, the first pixel electrode PXE1 may be electrically connected to at least one circuit element (for example, the fourth transistor ST4 and the sixth transistor ST6 of FIG. 4) included in the pixel circuit (for example, the pixel circuit PXC of FIG. 4) of the first sub-pixel SPX1 through a first contact hole CT1.

In addition, the first pixel electrode PXE1 may be electrically connected to a part of the light emitting element LE. For example, the first pixel electrode PXE1 may be electrically connected to a first conductivity type semiconductor layer (for example, a p-type semiconductor layer of a first light emitting unit EMU1) included in the first light emitting unit EMU1 of the light emitting element LE.

The second pixel electrode PXE2 may be electrically connected to the circuit element included in the second sub-pixel SPX2. For example, the second pixel electrode PXE2 may be electrically connected to at least one circuit element included in the pixel circuit (for example, the pixel circuit PXC of FIG. 4) of the second sub-pixel SPX2 through a second contact hole CT2.

In addition, the second pixel electrode PXE2 may be electrically connected to a part of the light emitting element LE. For example, the second pixel electrode PXE2 may be electrically connected to a first conductivity type semiconductor layer (for example, a p-type semiconductor layer of a second light emitting unit EMU2) included in the second light emitting unit EMU2 of the light emitting element LE.

The third pixel electrode PXE3 may be electrically connected to the circuit element included in the third sub-pixel SPX3. For example, the third pixel electrode PXE3 may be electrically connected to at least one circuit element included in the pixel circuit (for example, the pixel circuit PXC of FIG. 4) of the third sub-pixel SPX3 through a third contact hole CT3.

In addition, the third pixel electrode PXE3 may be electrically connected to a part of the light emitting element LE. For example, the third pixel electrode PXE3 may be electrically connected to a first conductivity type semiconductor layer (for example, a p-type semiconductor layer of a third light emitting unit EMU3) included in the third light emitting unit EMU3 of the light emitting element LE.

The common electrode CE may be electrically connected to the second power line VSL (see FIG. 4) to which the second driving voltage VSS (see FIG. 3) is applied, inside the display area DA and/or in the non-display area NDA (see FIGS. 1-3) . For example, the common electrode CE may be electrically connected to the second power line VSL located in the thin film transistor layer of the display panel 100 through a fourth contact hole CT4. In one or more embodiments, the common electrode CE may extend to the non-display area NDA, and may be electrically connected to the second power line VSL (for example, a part of the second power line VSL that is formed as a power bus line in the non-display area NDA) even in the non-display area NDA. In another embodiment, the fourth contact hole CT4 may not be formed in the display area DA. In this case, the common electrode CE may be electrically connected to the second power line VSL only in the non-display area NDA.

In addition, the common electrode CE may be electrically connected to a part of the light emitting element LE. For example, the common electrode CE may be electrically connected to the second conductivity type semiconductor layers (for example, the n-type semiconductor layers of each of the first light emitting unit EMU1, a second light emitting unit EMU2, and a third light emitting unit EMU3) included in the first light emitting unit EMU1, the second light emitting unit EMU2, and the third light emitting unit EMU3 of the light emitting element LE.

The light emitting element LE may be located on the pixel electrodes PXE and the common electrode CE of each pixel PX. For example, the light emitting element LE may be located on a part of each of the first pixel electrode PXE1, the second pixel electrode PXE2, the third pixel electrode PXE3, and the common electrode CE. The light emitting element LE may be electrically connected between each of the pixel electrodes PXE and the common electrode CE.

In one or more embodiments, the light emitting element LE may include the plurality of light emitting units EMU that constitute the light emitting element LE of each of the sub-pixels SPX and emit light of different colors. For example, the light emitting element LE of the first sub-pixel SPX1, the light emitting element LE of the second sub-pixel SPX2, and the light emitting element LE of the third sub-pixel SPX3 may be integrated into one light emitting element LE. In this case, the light emitting element LE may include the first light emitting unit EMU1 that emits light of a first color (for example, light of a red wavelength band) corresponding to the emission wavelength of the first sub-pixel SPX1, the second light emitting unit EMU2 that emits light of a second color (for example, light of a green wavelength band) corresponding to the emission wavelength of the second sub-pixel SPX2, and the third light emitting unit EMU3 that emits light of a third color (for example, light of a blue wavelength band) corresponding to the emission wavelength of the third sub-pixel SPX3. For example, the light emitting element LE may be a micro LED (for example, RGB 1-chip micro LED or single chip RGB micro LED) having a 1-chip structure in which a red light emitting element for emitting red light, a green light emitting element for emitting green light, and a blue light emitting element for emitting blue light are integrated into one chip.

The first light emitting unit EMU1 may be electrically connected between the first pixel electrode PXE1 and the common electrode CE. The first light emitting unit EMU1 may form a first color light emitting element, for example, a red light emitting element, included in the first sub-pixel SPX1.

The second light emitting unit EMU2 may be electrically connected between the second pixel electrode PXE2 and the common electrode CE. The second light emitting unit EMU2 may form a second color light emitting element, for example, a green light emitting element, included in the second sub-pixel SPX2.

The third light emitting unit EMU3 may be electrically connected between the third pixel electrode PXE3 and the common electrode CE. The third light emitting unit EMU3 may form a third color light emitting element, for example, a blue light emitting element, included in the third sub-pixel SPX3.

The first sub-pixel SPX1 may include a light emitting part including the first pixel electrode PXE1, the light emitting element LE (for example, the first color light emitting element including the first light emitting unit EMU1), and the common electrode CE. In one or more embodiments, the first sub-pixel SPX1 may further include a driving part (for example, the pixel circuit PXC electrically connected to the first pixel electrode PXE1) electrically connected to the light emitting part. Accordingly, the emission timing or luminance of the first light emitting unit EMU1 may be independently controlled.

The second sub-pixel SPX2 may include a light emitting part including the second pixel electrode PXE2, the light emitting element LE (for example, the second color light emitting element including the second light emitting unit EMU2), and the common electrode CE. In one or more embodiments, the second sub-pixel SPX2 may further include a driving part (for example, the pixel circuit PXC electrically connected to the second pixel electrode PXE2) electrically connected to the light emitting part. Accordingly, the emission timing or luminance of the second light emitting unit EMU2 may be independently controlled.

The third sub-pixel SPX3 may include a light emitting part including the third pixel electrode PXE3, the light emitting element LE (for example, the third color light emitting element including the third light emitting unit EMU3), and the common electrode CE. In one or more embodiments, the third sub-pixel SPX3 may further include the driving part (for example, the pixel circuit PXC electrically connected to the third pixel electrode PXE3) electrically connected to the light emitting part. Accordingly, the emission timing or luminance of the third light emitting unit EMU3 may be independently controlled.

The display area DA may include pixel columns including the respective pixels PX arranged along the second direction DR2. In one or more embodiments, the first pixel electrodes PXE1 of the pixels PX included in each pixel column may be arranged along the second direction DR2. In addition, the second pixel electrodes PXE2 of the pixels PX included in each pixel column may be arranged along the second direction DR2, and the third pixel electrodes PXE3 of the pixels PX included in each pixel column may be arranged along the second direction DR2. However, the arrangement shape of the pixel electrodes PXE may be variously changed according to embodiments.

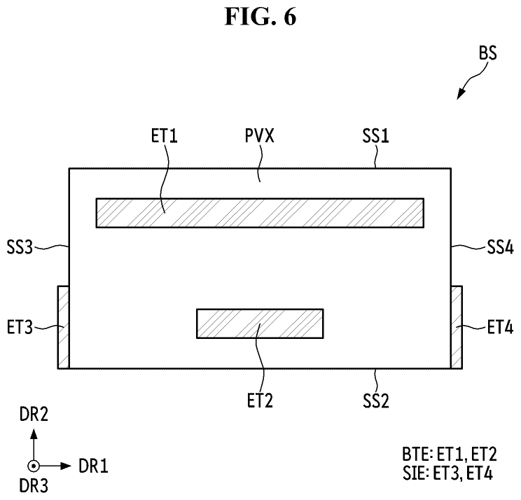

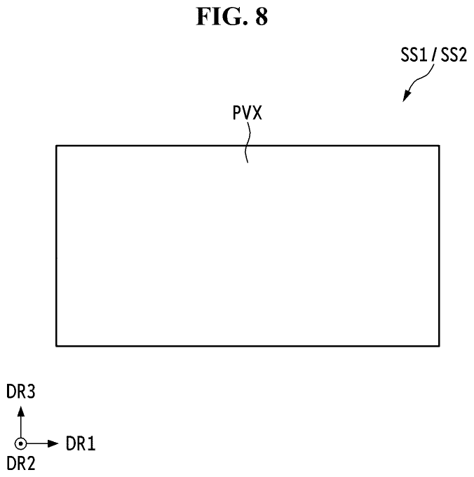

FIG. 6-10 are plan views showing a light emitting element according to one or more embodiments. For example, FIG. 6-10 show different side surfaces of the light emitting element LE illustrated in FIG. 5. For example, FIG. 6-10 show a bottom surface BS, a top surface TS, a first side surface SS1, a second side surface SS2, a third side surface SS3, and a fourth side surface SS4 of the light emitting element LE, respectively. Although FIG. 5-10 show an embodiment in which the light emitting element LE has a substantially rectangular parallelepiped shape, the shape of the light emitting element LE is not limited thereto.

Referring to FIG. 6-10 in addition to FIG. 5, the light emitting element LE according to one or more embodiments may include a semiconductor stack STC, a passivation film PVX covering at least a part of the semiconductor stack STC, and electrodes electrically connected to the semiconductor stack STC.

The semiconductor stack STC may include the plurality of light emitting units EMU (see FIG. 5) included in the light emitting element LE. Each light emitting unit EMU may include an active layer, and a first conductivity type semiconductor layer and a second conductivity type semiconductor layer located on different surfaces of the active layer. The detailed description of the detailed structure of the semiconductor stack STC will be provided later.

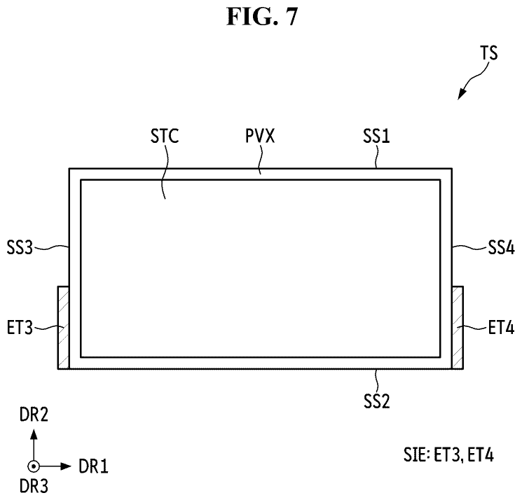

The passivation film PVX may be located on the side surface of the semiconductor stack STC. The passivation film PVX may cover the side surfaces of the light emitting units EMU included in the semiconductor stack STC. The passivation film PVX may be further located on a part of the bottom surface of the semiconductor stack STC. The passivation film PVX may be exposed on the bottom surface BS, the first side surface SS1, the second side surface SS2, the third side surface SS3, and the fourth side surface SS4 of the light emitting element LE. In one or more embodiments, the end of the passivation film PVX may be exposed even on the top surface TS of the light emitting element LE. Although FIG. 7 illustrates an embodiment in which the passivation film PVX does not cover the top surface of the semiconductor stack STC and, thus, the semiconductor stack STC is exposed on the top surface TS of the light emitting element LE, the present disclosure is not limited thereto. For example, the passivation film PVX may cover the top surface of the semiconductor stack STC.

The light emitting element LE may include a plurality of electrodes electrically connected to the plurality of light emitting units EMU. For example, the light emitting element LE may include the plurality of electrodes for independently and/or individually driving the plurality of light emitting units EMU. For example, the light emitting element LE may include a second electrode ET2, a third electrode ET3, and a fourth electrode ET4 for individually connecting the first conductive semiconductors of the first light emitting unit EMU1 (see FIG. 5), the second light emitting unit EMU2 (see FIG. 5), and the third light emitting unit EMU3 (see FIG. 5) to the first pixel electrode PXE1, the second pixel electrode PXE2, and the third pixel electrode PXE3, respectively. In addition, the light emitting element LE may further include at least one first electrode ET1 for electrically connecting the second conductive semiconductors of the first light emitting unit EMU1, the second light emitting unit EMU2, and the third light emitting unit EMU3 to the common electrode CE. In the case of the display panel 100 of a common-cathode structure (for example, the display panel 100 including the sub-pixel SPX in which the anode electrode of the light emitting element LE is connected to the pixel circuit PXC and the cathode electrode of the light emitting element LE is connected to the second power line VSL as in the embodiment of FIG. 4), the first conductivity type semiconductor layers of the first light emitting unit EMU1, the second light emitting unit EMU2, and the third light emitting unit EMU3 may be p-type semiconductor layers, and the second conductivity type semiconductor layers of the first light emitting unit EMU1, the second light emitting unit EMU2, and the third light emitting unit EMU3 may be n-type semiconductor layers. On the contrary, in the case of the display panel 100 of the common-anode structure, the first conductivity type semiconductor layers of the first light emitting unit EMU1, the second light emitting unit EMU2, and the third light emitting unit EMU3 may be n-type semiconductor layers, and the second conductivity type semiconductor layers of the first light emitting unit EMU1, the second light emitting unit EMU2, and the third light emitting unit EMU3 may be p-type semiconductor layers.

Accordingly, the light emitting element LE may include electrodes of which number is greater than the number of the plurality of light emitting units EMU. For example, the light emitting element LE including the first light emitting unit EMU1, the second light emitting unit EMU2, and the third light emitting unit EMU3 may include at least four electrodes. In one or more embodiments, when the second semiconductor layers of at least two light emitting units EMU from among the first light emitting unit EMU1, the second light emitting unit EMU2, and the third light emitting unit EMU3 are electrically connected to the common electrode CE through different electrodes, the light emitting element LE may include at least five electrodes. For example, when the second semiconductor layers of the first light emitting unit EMU1, the second light emitting unit EMU2, and the third light emitting unit EMU3 are electrically connected to the common electrode CE through different electrodes, the light emitting element LE may include six electrodes.

In the embodiment of FIG. 6-10, the light emitting element LE may include one first electrode ET1 commonly connected to the second semiconductor layers of the first light emitting unit EMU1, the second light emitting unit EMU2, and the third light emitting unit EMU3, and the second electrode ET2, the third electrode ET3, and the fourth electrode ET4 that are individually connected to the first semiconductor layers of the first light emitting unit EMU1, the second light emitting unit EMU2, and the third light emitting unit EMU3. Accordingly, the number of electrodes included in the light emitting element LE may be reduced or minimized, and the efficiency and reliability of a bonding process for locating the light emitting element LE inside the display panel 100 may be increased.

In one or more embodiments, at least one electrode from among the first electrode ET1, the second electrode ET2, the third electrode ET3, and the fourth electrode ET4 of the light emitting element LE may be formed as a side electrode SIE. At least one other electrode from among the first electrode ET1, the second electrode ET2, the third electrode ET3, and the fourth electrode ET4 of the light emitting element LE may be formed as a bottom electrode BTE.

The bottom electrode BTE may be located on the bottom surface BS of the light emitting element LE. For example, the bottom electrode BTE may be located on the bottom surface of the semiconductor stack STC and/or the passivation film PVX. In one or more embodiments, the bottom electrode BTE may include the first electrode ET1 and the second electrode ET2 that are separated from each other.

The first electrode ET1 may be located on the common electrode CE and may be electrically connected to the common electrode CE. In one or more embodiments, the first electrode ET1 may be bonded onto the top surface of the common electrode CE by a bonding process and/or the like.

The first electrode ET1 may be electrically connected to at least one semiconductor layer included in the semiconductor stack STC. For example, the first electrode ET1 may be located on a part of the bottom surface of the semiconductor stack STC and may be electrically connected to the second conductivity type semiconductor layers of the light emitting units EMU included in the semiconductor stack STC while penetrating at least a part of the semiconductor stack STC.

The second electrode ET2 may be located on the first pixel electrode PXE1 and may be electrically connected to the first pixel electrode PXE1. In one or more embodiments, the second electrode ET2 may be bonded onto the top surface of the first pixel electrode PXE1 by a bonding process and/or the like.

The second electrode ET2 may be electrically connected to at least one semiconductor layer included in the semiconductor stack STC. For example, the second electrode ET2 may be located on a part of the bottom surface of the semiconductor stack STC and may be electrically connected to the first conductivity type semiconductor layer of the first light emitting unit EMU1 included in the semiconductor stack STC. In one or more embodiments, the second electrode ET2 may be electrically connected to the first conductivity type semiconductor layer of the first light emitting unit EMU1 while penetrating at least a part of the semiconductor stack STC. In another embodiment, when the first conductivity type semiconductor layer of the first light emitting unit EMU1 is located at the lowermost portion of the semiconductor stack STC, the second electrode ET2 may be in contact with the bottom surface of the first conductivity type semiconductor layer of the first light emitting unit EMU1 without penetrating the semiconductor stack STC.

The side electrode SIE may be located on the side surface of the light emitting element LE. For example, the side electrode SIE may be located on the side surface of the passivation film PVX. In one or more embodiments, the side electrode SIE may include the third electrode ET3 located on the third side surface SS3 of the light emitting element LE, and the fourth electrode ET4 located on the fourth side surface SS4 of the light emitting element LE.

The third electrode ET3 may be located on the second pixel electrode PXE2 and electrically connected to the second pixel electrode PXE2. The third electrode ET3 may be electrically connected to at least one semiconductor layer included in the semiconductor stack STC. For example, the third electrode ET3 may be located on a part of the side surface of the passivation film PVX on the third side surface SS3 of the light emitting element LE and may be electrically connected to the first conductivity type semiconductor layer of the second light emitting unit EMU2 included in the semiconductor stack STC. In one or more embodiments, the third electrode ET3 may be electrically connected to the semiconductor stack STC on the side surface of the semiconductor stack STC. For example, the third electrode ET3 may be in contact the side surface of the first conductivity type semiconductor layer of the second light emitting unit EMU2 while penetrating the passivation film PVX on the side surface of the semiconductor stack STC.

In one or more embodiments, the third electrode ET3 may be located only on a part of the third side surface SS3 of the light emitting element LE. For example, the third electrode ET3 may be located on a part of the side surface of the passivation film PVX that overlaps the second pixel electrode PXE2. Accordingly, the third electrode ET3 may be located only on a part of the third side surface SS3 of the light emitting element LE at a position corresponding to the second pixel electrode PXE2. For example, the third electrode ET3 may be located only on a part of the third side surface SS3 of the light emitting element LE located on the second pixel electrode PXE2, and may not be located on another part of the third side surface SS3 of the light emitting element LE located on the common electrode CE. In addition, the third electrode ET3 may not be located on the first side surface SS1 and the second side surface SS2 of the light emitting element LE. Accordingly, electrical stability between the common electrode CE and the pixel electrodes PXE other than the second pixel electrode PXE2 and the third electrode ET3, and electrical stability between different electrodes of the light emitting element LE may be secured. For example, short circuit defects may be effectively prevented by sufficiently securing a separation distance between the first pixel electrode PXE1 and the third electrode ET3, a separation distance between the common electrode CE and the third electrode ET3, and a separation distance between the first, second, third, and fourth electrodes ET1, ET2, ET3, and ET4 of the light emitting element LE.

The fourth electrode ET4 may be located on the third pixel electrode PXE3 and electrically connected to the third pixel electrode PXE3. The fourth electrode ET4 may be electrically connected to at least one semiconductor layer included in the semiconductor stack STC. For example, the fourth electrode ET4 may be located on a part of the side surface of the passivation film PVX on the fourth side surface SS4 of the light emitting element LE and may be electrically connected to the first conductivity type semiconductor layer of the third light emitting unit EMU3 included in the semiconductor stack STC. In one or more embodiments, the fourth electrode ET4 may be electrically connected to the semiconductor stack STC on the side surface of the semiconductor stack STC. For example, the fourth electrode ET4 may be in contact the side surface of the first conductivity type semiconductor layer of the third light emitting unit EMU3 while penetrating the passivation film PVX on the side surface of the semiconductor stack STC.

In one or more embodiments, the fourth electrode ET4 may be located only on a part of the fourth side surface SS4 of the light emitting element LE. For example, the fourth electrode ET4 may be located on a part of the side surface of the passivation film PVX that overlaps the third pixel electrode PXE3. Accordingly, the fourth electrode ET4 may be located only on a part of the fourth side surface SS4 of the light emitting element LE at a position corresponding to the third pixel electrode PXE3. For example, the fourth electrode ET4 may be located only on a part of the fourth side surface SS4 of the light emitting element LE located on the third pixel electrode PXE3, and may not be located on another part of the fourth side surface SS4 of the light emitting element LE located on the common electrode CE. In addition, the fourth electrode ET4 may not be located on the first side surface SS1 and the second side surface SS2 of the light emitting element LE. Accordingly, electrical stability between the common electrode CE and the pixel electrodes PXE other than the third pixel electrode PXE3 and the fourth electrode ET4, and electrical stability between different electrodes of the light emitting element LE may be secured. For example, short circuit defects may be effectively prevented by sufficiently securing a separation distance between the first pixel electrode PXE1 and the fourth electrode ET4, a separation distance between the common electrode CE and the fourth electrode ET4, and a separation distance between the first, second, third, and fourth electrodes ET1, ET2, ET3, and ET4 of the light emitting element LE.

FIG. 11 is a cross-sectional view illustrating a display area of a display panel according to one or more embodiments. FIG. 12 is a cross-sectional view illustrating a display area of a display panel according to one or more embodiments. For example, FIGS. 11 and 12 show an example of the cross-section of the pixel PX corresponding to the lines X1-X1′ and X2-X2′ of FIG. 5, respectively.

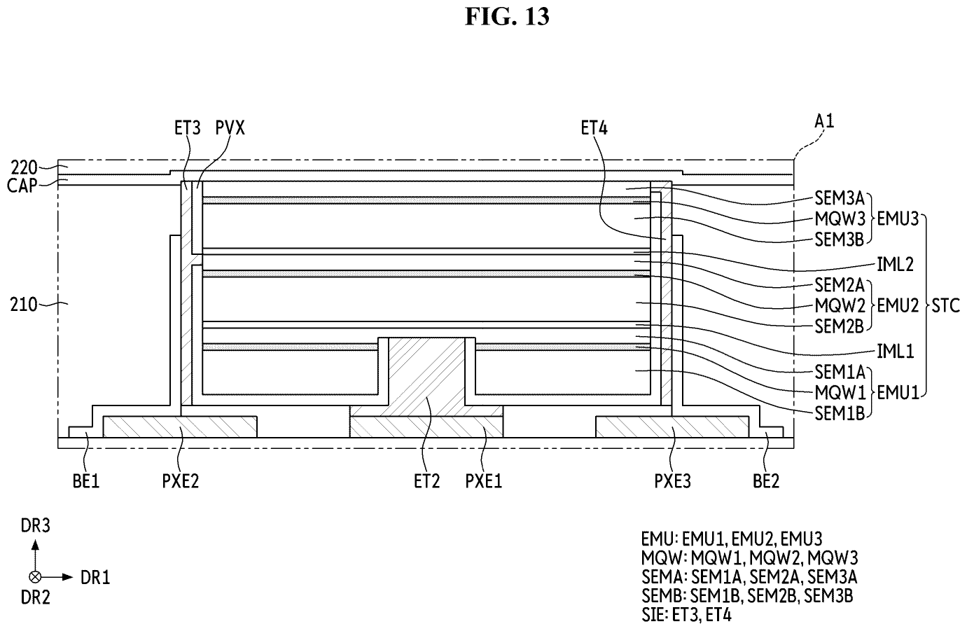

FIG. 13 is a cross-sectional view showing an area A1 of FIG. 11 in detail. For example, FIG. 13 shows the cross-section of the light emitting element LE according to one or more embodiments in detail.

Referring to FIG. 11-13 in addition to FIG. 5-10, a substrate SUB may be made of an insulating material such as glass, polymer resin, and/or the like. When the substrate SUB includes polymer resin, it may be a flexible substrate that can be stretched. The polymer resin may include acryl resin, epoxy resin, phenolic resin, polyamide resin, and/or polyimide resin.

The barrier layer BR may be located on the substrate SUB. The barrier layer BR is a film for protecting transistors of the thin film transistor layer TFTL and the light emitting elements LE arranged on the thin film transistor layer TFTL from moisture permeating through the substrate SUB which is susceptible to moisture permeation. The barrier layer BR may include a plurality of inorganic films that are alternately stacked.

The thin film transistor TFT1 may be located on the barrier layer BR. In one or more embodiments, the first thin film transistor TFT1 may be one of the fourth transistor ST4 or the sixth transistor ST6 shown in FIG. 4. The thin film transistor TFT1 may include an active layer ACT1 and a gate electrode G1.

FIGS. 11 and 12 illustrate schematic cross-sections of the thin film transistor TFT1 included in each sub-pixel SPX. In FIGS. 11 and 12, the thin film transistor TFT1 located at position corresponding to each sub-pixel SPX (for example, the first sub-pixel SPX1, the second sub-pixel SPX2, and the third sub-pixel SPX3 of FIG. 5) may be one transistor (for example, one of the driving transistor DT or the first to sixth transistors ST1, ST2, ST3, ST4, ST5, and ST6) of FIG. 3) among the transistors included in each sub-pixel SPX.

An active layer ACT1 of the thin film transistor TFT1 may be located on the barrier layer BR. The active layer ACT1 of the thin film transistor TFT1 may include polycrystalline silicon, monocrystalline silicon, low-temperature polycrystalline silicon, and/or amorphous silicon. Alternatively, the active layer ACT1 of the thin film transistor TFT1 may include an oxide semiconductor (for example, indium gallium zinc oxide (IGZO), indium gallium zinc tin oxide (IGZTO), and/or indium gallium tin oxide (IGTO)).

The active layer ACT1 may include a channel region CHA1, a source region S1, and a drain region D1. The channel region CHA1 may overlap the gate electrode G1 in the third direction DR3. The source region S1 may be located on one side of the channel region CHA1, and the drain region D1 may be located on the other side of the channel region CHA1. At least a part of the source region S1 and the drain region D1 may not overlap the gate electrode G1 in the third direction DR3. The conductivity (for example, carrier concentration) of the source region S1 and the drain region D1 may be higher than the conductivity of the channel region CHA1.

The first gate insulating layer 131 may be located on the active layer ACT1 of the thin film transistor TFT1 and on the barrier layer BR.

A first gate metal layer may be located on the first gate insulating layer 131. The first gate metal layer may include the gate electrode G1 of the thin film transistor TFT1 and the first capacitor electrode CAE1. The gate electrode G1 of the thin film transistor TFT1 may overlap the active layer ACT1 of the thin film transistor TFT1 in the third direction DR3.

A second gate insulating layer 132 may be located on the gate electrode G1 and of the thin film transistor TFT1, the first capacitor electrode CAE1, and on the first gate insulating layer 131.

A second gate metal layer may be located on the second gate insulating layer 132. The second gate metal layer may include a second capacitor electrode CAE2. The second capacitor electrode CAE2 may overlap the first capacitor electrode CAE1 in the third direction DR3. The first capacitor C1 (see FIG. 4) may be formed by the first capacitor electrode CAE1, the second capacitor electrode CAE2, and the second gate insulating layer 132.

An interlayer insulating layer 141 may be located on the second capacitor electrode CAE2 and the second gate insulating layer 132.

A first data metal layer may be located on the interlayer insulating layer 141. The first data metal layer may include a first source connection electrode PCE1. The first source connection electrode PCE1 may be connected to the drain region D1 of the active layer ACT1 through a first source contact hole PCT1 penetrating the first gate insulating layer 131, the second gate insulating layer 132, and the interlayer insulating layer 141.

A first planarization layer 160 for flattening a stepped portion formed by the thin film transistor TFT1 may be located on the first source connection electrode PCE1 and on the interlayer insulating layer 141.

A second data metal layer may be located on the first planarization layer 160. The second data metal layer may include a second source connection electrode PCE2. The second source connection electrode PCE2 may be connected to the first source connection electrode PCE1 through a second source contact hole PCT2 penetrating the first planarization layer 160.

A second planarization layer 180 may be located on the second source connection electrode PCE2 and on the first planarization layer 160.

The barrier layer BR, the first gate insulating layer 131, the second gate insulating layer 132, and the interlayer insulating layer 141 may be formed as at least one inorganic insulating layer including an inorganic insulating material (for example, silicon nitride (SiNₓ), silicon oxide nitride (SiON), silicon oxide (SiOₓ), titanium oxide (TiOₓ), and/or aluminum oxide (AlOₓ)). Each of the barrier layer BR, the first gate insulating layer 131, the second gate insulating layer 132, and the interlayer insulating layer 141 may be formed in a single-layer or multi-layer structure.

The first gate metal layer, the second gate metal layer, the first data metal layer, and the second data metal layer may include a conductive material (for example, molybdenum (Mo), aluminum (Al), chromium (Cr), gold (Au), titanium (Ti), nickel (Ni), neodymium (Nd), and/or copper (Cu), and/or an alloy thereof). Each of the first gate metal layer, the second gate metal layer, the first data metal layer, and the second data metal layer may be formed in a single-layer or multi-layer structure.

The first planarization layer 160 and the second planarization layer 180 may include at least one organic insulating layer containing an organic insulating material (e.g., acryl resin, epoxy resin, phenolic resin, polyamide resin, polyimide resin, and/or the like). Each of the first planarization layer 160 and the second planarization layer 180 may be formed in a single-layer or multi-layer structure.

A light emitting element layer may be located on the second planarization layer 180. The light emitting element layer may include the pixel electrodes PXE, the common electrode CE, and the light emitting element LE of each pixel PX. The light emitting element layer may further include a first organic layer 210, a partition wall BWL, a capping layer CAP, and a third planarization layer 220 (or a second organic layer) located around the light emitting element LE. The light emitting element layer may further include first and second connection electrodes BE1 and BE2.

A pixel electrode layer and the partition wall BWL may be located on the second planarization layer 180. The light emitting element LE and the first and second connection electrodes BE1 and BE2 may be located on the pixel electrode layer. The first organic layer 210 may be located in the space between the light emitting element LE and the partition wall BWL. The first organic layer 210 and the partition wall BWL may be around (e.g., may surround) the pixel electrode layer, the light emitting element LE, and the first and second connection electrodes BE1 and BE2.

The pixel electrode layer may include the common electrode CE and the pixel electrodes PXE (for example, the first pixel electrode PXE1, the second pixel electrode PXE2, and the third pixel electrode PXE3) of each of the pixels PX.

Each of the pixel electrodes PXE may be electrically connected to the second source connection electrode PCE2 of each sub-pixel SPX through a contact hole (for example, the first contact hole CT1, a second contact hole CT2, or a third contact hole CT3 of FIG. 5) penetrating the second planarization layer 180. Each of the pixel electrodes PXE may be electrically connected to the thin film transistor TFT1 via the first source connection electrode PCE1 and the second source connection electrode PCE2.

The pixel electrode layer may include a conductive material (e.g., molybdenum (Mo), aluminum (Al), chromium (Cr), gold (Au), titanium (Ti), nickel (Ni), neodymium (Nd) and/or copper (Cu), and/or an alloy thereof), and may be formed as a single layer or multiple layers. For example, the pixel electrodes PXE and the common electrode CE may each be formed in a single-layer or multi-layer conductive pattern including at least one conductive material. The pixel electrodes PXE and the common electrode CE may be formed concurrently (e.g., simultaneously), and thus may have the same conductive material and cross-sectional structure.

In one or more embodiments, the common electrode CE and the pixel electrodes PXE of the pixel electrode layer may each include a reflective layer including a metal having high reflectivity. Accordingly, the light directed to the lower side of the light emitting element LE may be reflected, thereby improving the luminance and light efficiency of the pixel PX.

The light emitting element LE may be located on the pixel electrodes PXE and the common electrode CE. In one or more embodiments, the light emitting element LE may include an inorganic material such as gallium nitride (GaN). In one or more embodiments, the light emitting element LE may have a length of several tens to several hundreds of μmin each of the first direction DR1, the second direction DR2, and the third direction DR3. For example, the light emitting element LE may have a length of 100 μm or less in each of the first direction DR1, the second direction DR2, and the third direction DR3.

The light emitting element LE may be formed by growing on a semiconductor substrate such as a silicon substrate or sapphire substrate. The light emitting element LE may be transferred directly from the semiconductor substrate onto the pixel electrodes PXE and the common electrode CE. Alternatively, the light emitting element LE may be transferred onto the common electrode CE and the pixel electrodes PXE through an electrostatic method using an electrostatic head or a stamping method using an elastic polymer material such as PDMS or silicon as a transfer substrate.

The light emitting element LE may include the semiconductor stack STC, the passivation film PVX, the first electrode ET1, the second electrode ET2, the third electrode ET3, and the fourth electrode ET4. In one or more embodiments, the light emitting element LE may further include a third insulating layer INS3 and a fourth insulating layer INS4 located on a part of the first electrode ET1. The fourth insulating layer INS4 may be omitted.

The semiconductor stack STC may include the plurality of light emitting units EMU as illustrated in FIG. 13. For example, the semiconductor stack STC may include the first light emitting unit EMU1, the second light emitting unit EMU2, and the third light emitting unit EMU3. The first light emitting unit EMU1 may also be referred to as “first stack” or “first light emitting element.” The second light emitting unit EMU2 may also be referred to as “second stack” or a “second light emitting element.” The third light emitting unit EMU3 may also be referred to as “third stack” or a “third light emitting element.”

The semiconductor stack STC may have a structure in which the first light emitting unit EMU1, the second light emitting unit EMU2, and the third light emitting unit EMU3 are stacked. For example, the first light emitting unit EMU1, the second light emitting unit EMU2, and the third light emitting unit EMU3 may overlap each other in the third direction DR3.

In one or more embodiments, the first light emitting unit EMU1, the second light emitting unit EMU2, and the third light emitting unit EMU3 may be sequentially arranged along the third direction DR3. However, the stacking order of the first light emitting unit EMU1, the second light emitting unit EMU2, and the third light emitting unit EMU3 may vary depending on embodiments.

Each of the plurality of light emitting units EMU may include a first conductivity type semiconductor layer SEMA, an active layer MQW (also referred to as “light emitting layer”), and a second conductivity type semiconductor layer SEMB. The active layer MQW may be located between the first conductivity type semiconductor layer SEMA and the second conductivity type semiconductor layer SEMB. In one or more embodiments, the thickness of the second conductivity type semiconductor layer SEMB may be greater than the thickness of the first conductivity type semiconductor layer SEMA.

The first light emitting unit EMU1 may include a first semiconductor layer SEM1A, a first active layer MQW1 (also referred to as “first light emitting layer”), and a second semiconductor layer SEM1B. The first semiconductor layer SEM1A may be the first conductivity type semiconductor layer SEMA (for example, a p-type semiconductor layer), and the second semiconductor layer SEM1B may be the second conductivity type semiconductor layer SEMB (for example, an n-type semiconductor layer). The first semiconductor layer SEM1A and the second semiconductor layer SEM1B may be located on different surfaces of the first active layer MQW1. For example, the first semiconductor layer SEM1A may be located on the top surface of the first active layer MQW1, and the second semiconductor layer SEM1B may be located on the bottom surface of the first active layer MQW1.

The second light emitting unit EMU2 may include a third semiconductor layer SEM2A, a second active layer MQW2 (also referred to as “second light emitting layer”), and a fourth semiconductor layer SEM2B. The third semiconductor layer SEM2A may be the first conductivity type semiconductor layer SEMA (for example, a p-type semiconductor layer), and the fourth semiconductor layer SEM2B may be the second conductivity type semiconductor layer SEMB (for example, an n-type semiconductor layer). The third semiconductor layer SEM2A and the fourth semiconductor layer SEM2B may be located on different surfaces of the second active layer MQW2. For example, the third semiconductor layer SEM2A may be located on the top surface of the second active layer MQW2, and the fourth semiconductor layer SEM2B may be located on the bottom surface of the second active layer MQW2.

The third light emitting unit EMU3 may include a fifth semiconductor layer SEM3A, a third active layer MQW3 (also referred to as “third light emitting layer”), and a sixth semiconductor layer SEM3B. The fifth semiconductor layer SEM3A may be the first conductivity type semiconductor layer SEMA (for example, a p-type semiconductor layer), and the sixth semiconductor layer SEM3B may be the second conductivity type semiconductor layer SEMB (for example, an n-type semiconductor layer). The fifth semiconductor layer SEM3A and the sixth semiconductor layer SEM3B may be located on different surfaces of the third active layer MQW3. For example, the fifth semiconductor layer SEM3A may be located on the top surface of the third active layer MQW3, and the sixth semiconductor layer SEM3B may be located on the bottom surface of the third active layer MQW3.

Each of the first conductivity type semiconductor layers SEMA (for example, the first semiconductor layer SEM1A, the third semiconductor layer SEM2A, and the fifth semiconductor layer SEM3A) may include a semiconductor material doped with a first conductive dopant. For example, each of the first conductivity type semiconductor layers SEMA may be a p-type semiconductor layer including gallium nitride (GaN) doped with a p-type dopant such as magnesium (Mg), zinc (Zn), calcium (Ca), strontium (Sr), barium (Ba), and/or the like. In another embodiment, in the case of the display panel 100 of a common-anode structure, each of the first conductivity type semiconductor layers SEMA may be an n-type semiconductor layer including gallium nitride (GaN) doped with an n-type dopant such as silicon (Si), germanium (Ge), tin (Sn), and/or the like.

Each of the second conductivity type semiconductor layers SEMB (for example, the second semiconductor layer SEM1B, the fourth semiconductor layer SEM2B, and the sixth semiconductor layer SEM3B) may include a semiconductor material doped with a second conductive dopant. For example, each of the second conductivity type semiconductor layers SEMB may be an n-type semiconductor layer including gallium nitride (GaN) doped with an n-type dopant. In another embodiment, in the case of the display panel 100 of a common-anode structure, each of the second conductivity type semiconductor layers SEMB may be a p-type semiconductor layer including gallium nitride (GaN) doped with a p-type dopant.

Each of the active layers MQW (for example, the first active layer MQW1, the second active layer MQW2, and the third active layer MQW3) may include the same semiconductor material as each of the first conductivity type semiconductor layer SEMA and the second conductivity type semiconductor layer SEMB. For example, when the first conductivity type semiconductor layers SEMA and the second conductivity type semiconductor layers SEMB include gallium nitride (GaN), each of the active layers MQW may include gallium nitride (GaN). For example, the active layers MQW may include gallium nitride (GaN), indium gallium nitride (InGaN), and/or aluminum gallium nitride (AlGaN). The active layer MQW included in each light emitting unit EMU may emit light by the recombination of electron-hole pairs that occur in response to an electric signal applied through each of the first conductivity type semiconductor layer SEMA and the second conductivity type semiconductor layer SEMB.

Each of the active layers MQW may be formed in a single or multiple quantum well structure. When each active layer MQW is formed in a multiple quantum well structure, the active layer MQW may include well layers and barrier layers that are alternately stacked. In one or more embodiments, each well layer may include InGaN, and each barrier layer may include GaN and/or AlGaN, but are not limited thereto. Alternatively, each active layer MQW may have a structure in which a semiconductor material having large band gap energy and a semiconductor material having small band gap energy are alternately stacked, and may include other Group III to Group V semiconductor materials according to the wavelength band of the emitted light.

The first active layer MQW1, the second active layer MQW2, and the third active layer MQW3 may emit light of the first color, light of the second color, and light of the third color, respectively. In one or more embodiments, when each active layer MQW includes indium gallium nitride (InGaN), the color of light emitted from each light emitting unit EMU may vary depending on the content of indium (In). For example, as the content of indium (In) increases, the wavelength band of the light emitted by the active layer MQW may shift to the red wavelength band, and as the content of indium (In) decreases, the wavelength band of the light emitted by the active layer may shift to the blue wavelength band. For example, when the first active layer MQW1, the second active layer MQW2, and the third active layer MQW3 emit light of a red wavelength band (for example, red light having a central wavelength band in a range of 610 nm to 650 nm), light of a green wavelength band (for example, green light having a central wavelength band in a range of 510 nm to 550 nm), and light in a blue wavelength band (for example, blue light having a central wavelength band in a range of 450 nm to 495 nm), respectively, the content of indium (In) of the second active layer MQW2 may be lower than the content of indium (In) of the first active layer MQW1, and may be higher than the content of indium (In) of the third active layer MQW3. For example, the content of indium (In) of the first active layer MQW1 may be approximately 30% to 45%, the content of indium (In) of the second active layer MQW2 may be approximately 20% to 30%, and the content of indium (In) of the third active layer MQW3 may be approximately 10% to 20%.

In one or more embodiments, the semiconductor stack STC may further include at least one intermediate layer located between the light emitting units EMU. For example, the semiconductor stack STC may further include a first intermediate layer IML1 located between the first light emitting unit EMU1 and the second light emitting unit EMU2, and a second intermediate layer IML2 located between the second light emitting unit EMU2 and the third light emitting unit EMU3.

The first intermediate layer IML1 and the second intermediate layer IML2 may include functional layers for reinforcing or improving the function (for example, luminous efficiency) or electrical characteristics (for example, reliability) of each of the first light emitting unit EMU1, the second light emitting unit EMU2, and the third light emitting unit EMU3. For example, each of the first intermediate layer IML1 and the second intermediate layer IML2 may include at least one of a tunnel functional layer (or a charge generation layer) for appropriately supplying or moving electrons and holes to adjacent light emitting units EMU, or a barrier layer (or an insulating layer) for stable individual driving of adjacent light emitting units EMU.

In addition, the semiconductor stack STC may further include an additional functional layer. For example, the semiconductor stack STC may further include an electron blocking layer, and/or the like. For example, the semiconductor stack STC may include the plurality of active layers MQW, and first conductivity type semiconductor layers SEMA and second conductivity type semiconductor layers SEMB that are located on different surfaces of the respective active layers MQW, and may selectively further include at least one intermediate layer and/or functional layer.

The passivation film PVX may be located on the side surface of the semiconductor stack STC. For example, the passivation film PVX may be around (e.g., may surround) the side surfaces (e.g., outer peripheral surfaces) of the first light emitting unit EMU1, the second light emitting unit EMU2, and the third light emitting unit EMU3. The passivation film PVX may further cover the side surfaces (e.g., outer peripheral surfaces) of the first intermediate layer IML1 and the second intermediate layer IML2.

The passivation film PVX may also be located on a part of the bottom surface of the semiconductor stack STC. For example, the passivation film PVX may partially or entirely cover the bottom surface of the second semiconductor layer SEM1B included in the first light emitting unit EMU1.

In one or more embodiments, the passivation film PVX may also be located on a part of the second electrode ET2. For example, the passivation film PVX may be located on the side surface of the second electrode ET2 penetrating the semiconductor stack STC, and may prevent the first active layer MQW1 and the second semiconductor layer SEM1B included in the first light emitting unit EMU1 from being in contact with the second electrode ET2.

The passivation film PVX may include a material suitable for protecting the semiconductor stack STC. For example, the passivation film PVX may be formed as an inorganic film including an inorganic insulating material such as silicon nitride (SiNₓ), silicon oxide nitride (SiON), silicon oxide (SiOₓ), titanium oxide (TiOₓ), and/or aluminum oxide (AlOₓ).

The first electrode ET1 of the light emitting element LE may be located on the common electrode CE. The second electrode ET2, the third electrode ET3, and the fourth electrode ET4 of the light emitting element LE may be located on the first pixel electrode PXE1, the second pixel electrode PXE2, and the third pixel electrode PXE3, respectively.

In one or more embodiments, the first electrode ET1 and the second electrode ET2 of the light emitting element LE may be the bottom electrodes BTE located on the bottom surface BS of the light emitting element LE. The third electrode ET3 and the fourth electrode ET4 of the light emitting element LE may be the side electrodes SIE located on the side surface (for example, the third side surface SS3 and the fourth side surface SS4) of the light emitting element LE.

The first electrode ET1 may be located on the common electrode CE and may be electrically connected to the common electrode CE. For example, the bottom surface of the first electrode ET1 may be in contact with the top surface of the common electrode CE. However, the present disclosure is not limited thereto. For example, an additional conductive layer (for example, a conductive layer including a bonding layer or a conductive ball) may be further located between the first electrode ET1 and the common electrode CE.

In addition, the first electrode ET1 may be electrically connected to the second conductivity type semiconductor layers SEMB of the semiconductor stack STC while penetrating at least a part of the semiconductor stack STC. For example, the first electrode ET1 may penetrate the first and second light emitting units EMU1 and EMU2 and the first and second intermediate layers IML1 and IML2 of the semiconductor stack STC, and may further penetrate the sixth semiconductor layer SEM3B of the third light emitting unit EMU3 by a partial thickness.

The first electrode ET1 may be in contact with the second conductivity type semiconductor layers SEMB, for example, the second semiconductor layer SEM1B and the fourth semiconductor layer SEM2B, included in the first and second light emitting units EMU1 and EMU2 at a portion penetrating the first and second light emitting units EMU1 and EMU2. Accordingly, the first electrode ET1 may be electrically connected to the second semiconductor layer SEM1B and the fourth semiconductor layer SEM2B.

The third insulating layer INS3 may be located between the first electrode ET1 and the first conductivity type semiconductor layers SEMA and the active layers MQW, for example, the first semiconductor layer SEM1A, the first active layer MQW1, the third semiconductor layer SEM2A, and the second active layer MQW2, included in the first and second light emitting units EMU1 and EMU2. For example, at a portion where the first electrode ET1 penetrates the semiconductor stack STC, the third insulating layer INS3 may cover the side surfaces of the first conductivity type semiconductor layers SEMA included in the first and second light emitting units EMU1 and EMU2, and may further cover the side surfaces of the active layers MQW included in the first and second light emitting units EMU1 and EMU2. Accordingly, the first electrode ET1 may be insulated from the first semiconductor layer SEM1A, the first active layer MQW1, the third semiconductor layer SEM2A, and the second active layer MQW2. In one or more embodiments, the third insulating layer INS3 may also be located between the first and second intermediate layers IML1 and IML2 and the first electrode ET1, but the present disclosure is not limited thereto. The third insulating layer INS3 may include an insulating material, for example, an inorganic insulating material. The third insulating layer INS3 may include the same material as the material of the passivation film PVX, but the present disclosure is not limited thereto.

The first electrode ET1 may be in contact the sixth semiconductor layer SEM3B of the third light emitting unit EMU3 at a portion penetrating the sixth semiconductor layer SEM3B. Accordingly, the first electrode ET1 may be electrically connected to the sixth semiconductor layer SEM3B. In one or more embodiments, the first electrode ET1 may not penetrate the fifth semiconductor layer SEM3A and the third active layer MQW3 of the third light emitting unit EMU3. For example, the top surface of the first electrode ET1 may be located under the third active layer MQW3 while being spaced (e.g., spaced apart) from the third active layer MQW3.

In one or more embodiments, the fourth insulating layer INS4 may be located on the top surface of the first electrode ET1 surrounded by the third light emitting unit EMU3. Accordingly, the first electrode ET1 and the third active layer MQW3 may be more stably insulated. The fourth insulating layer INS4 may include an insulating material, for example, an inorganic insulating material. The fourth insulating layer INS4 may include the same material as the material of the passivation film PVX, but the present disclosure is not limited thereto. The fourth insulating layer INS4 may be omitted.

The second electrode ET2 may be located on the first pixel electrode PXE1 and may be electrically connected to the first pixel electrode PXE1. For example, the bottom surface of the second electrode ET2 may be in contact with the top surface of the first pixel electrode PXE1. However, the present disclosure is not limited thereto. For example, an additional conductive layer (for example, a conductive layer including a bonding layer or a conductive ball) may be further located between the second electrode ET2 and the first pixel electrode PXE1.

In addition, the second electrode ET2 may be electrically connected to the first semiconductor layer SEM1A included in the first light emitting unit EMU1 while penetrating at least a part of the first light emitting unit EMU1. For example, the second electrode ET2 may be in contact with the first semiconductor layer SEM1A while penetrating a part of the first light emitting unit EMU1. The passivation film PVX may be located between the second electrode ET2 and the first active layer MQW1 and the second semiconductor layer SEM1B included in the first light emitting unit EMU1. Accordingly, the second electrode ET2 may be insulated from the first active layer MQW1 and the second semiconductor layer SEM1B.

The first electrode ET1 and the second electrode ET2 may be bonded onto the common electrode CE and the first pixel electrode PXE1, respectively, by a bonding method (for example, eutectic bonding) using heat and/or pressure, or a bonding method using a medium layer (for example, anisotropic conductive film including a conductive ball) including a conductive material. However, the bonding method or the bonding structure for connecting the first and second electrodes ET1 and ET2 to the light emitting element LE may vary depending on embodiments. The first electrode ET1 and the second electrode ET2 may include a conductive material suitable for each bonding method. For example, the first electrode ET1 and the second electrode ET2 may include a metal suitable for eutectic bonding, but the present disclosure is not limited thereto.

The third electrode ET3 may be located on the second pixel electrode PXE2 and electrically connected to the second pixel electrode PXE2. For example, the third electrode ET3 may be electrically connected to the second pixel electrode PXE2 via the first connection electrode BE1.

In addition, the third electrode ET3 may be electrically connected to the third semiconductor layer SEM2A included in the second light emitting unit EMU2 on the side surface of the semiconductor stack STC. For example, the third electrode ET3 may be in contact with the side surface of the third semiconductor layer SEM2A while penetrating the passivation film PVX at a position corresponding to the third semiconductor layer SEM2A.

The fourth electrode ET4 may be located on the third pixel electrode PXE3 and electrically connected to the third pixel electrode PXE3. For example, the fourth electrode ET4 may be electrically connected to the third pixel electrode PXE3 via the second connection electrode BE2.

In addition, the fourth electrode ET4 may be electrically connected to the fifth semiconductor layer SEM3A included in the third light emitting unit EMU3 on the side surface of the semiconductor stack STC. For example, the fourth electrode ET4 may be in contact with the side surface of the fifth semiconductor layer SEM3A while penetrating the passivation film PVX at a position corresponding to the fifth semiconductor layer SEM3A. Alternatively, the fourth electrode ET4 may be located on the upper edge of the passivation film PVX and may be in contact with the side surface of the fifth semiconductor layer SEM3A.

In one or more embodiments, the third electrode ET3 and the fourth electrode ET4 may include a transparent conductive material. For example, the third electrode ET3 and the fourth electrode ET4 may include a transparent conductive material having both conductivity and a light transmitting property. For example, each of the third electrode ET3 and the fourth electrode ET4 may include a transparent conductive oxide (TCO) having excellent conductivity and transparency, such as indium tin oxide (ITO) and/or indium zinc oxide (IZO). When the third electrode ET3 and the fourth electrode ET4 are formed concurrently (e.g., simultaneously), the third electrode ET3 and the fourth electrode ET4 may include the same transparent conductive material.

Because each of the third electrode ET3 and the fourth electrode ET4 is formed as a transparent electrode, the amount of light that transmits the third electrode ET3 and the fourth electrode ET4 and reaches the reflective film RF of the partition wall BWL may increase. Accordingly, the light reflected by the reflective film RF may be increased, thereby increasing the light emission ratio of the pixel PX. Accordingly, the luminance and light efficiency of the pixel PX may be improved.

The first connection electrode BE1 may be located on the second pixel electrode PXE2 and the third electrode ET3 and electrically connect the second pixel electrode PXE2 to the third electrode ET3. For example, the first connection electrode BE1 may be directly located on a part of the second pixel electrode PXE2 and the third electrode ET3 to be in contact with the second pixel electrode PXE2 and the third electrode ET3, and thus may be electrically connected to the second pixel electrode PXE2 and the third electrode ET3.

The second connection electrode BE2 may be located on the third pixel electrode PXE3 and the fourth electrode ET4 and electrically connect the third pixel electrode PXE3 to the fourth electrode ET4. For example, the second connection electrode BE2 may be directly located on a part of the third pixel electrode PXE3 and the fourth electrode ET4 to be in contact with the third pixel electrode PXE3 and the fourth electrode ET4, and thus may be electrically connected to the third pixel electrode PXE3 and the fourth electrode ET4.

Each of the first connection electrode BE1 and the second connection electrode BE2 may include a conductive material. For example, each of the first connection electrode BE1 and the second connection electrode BE2 may include molybdenum (Mo), aluminum (Al), chromium (Cr), gold (Au), titanium (Ti), nickel (Ni), neodymium (Nd), and/or copper (Cu), or a transparent conductive material such as indium-tin oxide (ITO) and/or indium-zinc oxide (IZO).

In one or more embodiments, the first connection electrode BE1 and the second connection electrode BE2 may include a transparent conductive material. In this case, the amount of light that transmits via the first connection electrode BE1 and the second connection electrode BE2 and reaches the reflective film RF of the partition wall BWL may increase. Accordingly, the light reflected by the reflective film RF may be increased, thereby increasing the light emission ratio of the pixel PX.

In another embodiment, the first connection electrode BE1 and the second connection electrode BE2 may include a metal having high reflectivity (for example, aluminum (Al)). Accordingly, from among the light emitted from the light emitting element LE, light that has reached the first connection electrode BE1 and the second connection electrode BE2 of the light emitting element LE may be reflected by the first connection electrode BE1 and the second connection electrode BE2 and may travel in the upward direction of the light emitting element LE. Accordingly, the amount of light emitted to the upper side of the light emitting element LE may be increased.

The partition wall BWL may be around (e.g., surround) the light emitting element LE at a position spaced (e.g., spaced apart) from the light emitting element LE. The partition wall BWL may define a light transmitting area through which light emitted from the light emitting element LE may transmit, for example, the emission area of the pixel PX. For example, the partition wall BWL may be located in a non-emission area around the emission area to be around (e.g., to surround) each emission area including the area where the light emitting element LE is located and its neighboring part, and may be opened to correspond to the emission area.

In one or more embodiments, the partition wall BWL may be formed to have a height less than or equal to the height of the light emitting element LE (e.g., the partition wall BWL may be have a height less than or equal to the height of the light emitting element LE in the third direction DR3). In this case, the light emitting element LE may be more easily located on the pixel electrodes PXE and the common electrode CE. For example, it is advantageous in that the light emitting element LE may be easily transferred during a transfer process of the light emitting element LE.

The partition wall BWL may include a bank BNK defining the shape of the partition wall BWL and a first insulating layer INS1 covering the bank BNK. In one or more embodiments, the partition wall BWL may further include the reflective film RF located on the first insulating layer INS1, and a second insulating layer INS2 covering the reflective film RF.

The bank BNK may include an organic material. For example, the bank BNK may be formed as an organic film including an organic material such as acrylic resin, epoxy resin, phenolic resin, polyamide resin, and/or polyimide resin, but the present disclosure is not limited thereto.

The first insulating layer INS1 may include an inorganic material. For example, the first insulating layer INS1 may include an inorganic material such as silicon nitride (SiNₓ), silicon oxide nitride (SiON), silicon oxide (SiOₓ), titanium oxide (TiOₓ), and/or aluminum oxide (AlOₓ).

The reflective film RF may be located on the side surface of the bank BNK. In one or more embodiments, the reflective film RF may also be located on the top surface of the bank BNK. For example, the reflective film RF may entirely cover the bank BNK.

The reflective film RF may face the side surface of the light emitting element LE. The case where the reflective film RF faces the side surface of the light emitting element LE includes the case where the reflective film RF horizontally faces at least a part of the side surface of the light emitting element LE at the same height, and may also include the case where the reflective film RF is located at a position and/or height where the light emitted from the light emitting element LE in the lateral direction may reach.

The reflective film RF may include a material having high light reflectivity, for example, a metal such as aluminum (Al). Alternatively, the reflective film RF may be formed as a distributed Bragg reflector including inorganic films (for example, silicon nitride (SiNₓ), silicon oxide nitride (SiON), silicon oxide (SiOₓ), titanium oxide (TiOₓ), and/or aluminum oxide (AlOₓ)) that have different refractive indices and are arranged alternately. The light transmitted in the lateral direction of the light emitting element LE may be reflected by the reflective film RF, thereby increasing the light emission ratio of the pixel PX.

The second insulating layer INS2 may include an inorganic material. For example, the second insulating layer INS2 may include an inorganic material such as silicon nitride (SiNₓ), silicon oxide nitride (SiON), silicon oxide (SiOₓ), titanium oxide (TiOₓ), and/or aluminum oxide (AlOₓ).

The first organic layer 210 may be filled between the light emitting element LE and the partition wall BWL. For example, the first organic layer 210 may entirely or partially cover the side surface of the light emitting element LE. In one or more embodiments, the first organic layer 210 may be formed to have a height at which the first connection electrode BE1 and the second connection electrode BE2 may be covered, and may be formed to have a height less than or equal to the height of the light emitting element LE, but the present disclosure is not limited thereto.

The first organic layer 210 may include an organic material. For example, the first organic layer 210 may be formed as an organic film including an organic material such as acryl resin, epoxy resin, phenolic resin, polyamide resin, polyimide resin, and/or the like. The first organic layer 210 may alleviate the stepped portion caused by the light emitting element LE.

The capping layer CAP may be located on the light emitting elements LE, the partition wall BWL, and the first organic layer 210. The capping layer CAP may include a material suitable for protecting the light emitting elements LE. For example, the capping layer CAP may include an inorganic material such as silicon nitride (SiNₓ), silicon oxide nitride (SiON), silicon oxide (SiOₓ), titanium oxide (TiOₓ), and/or aluminum oxide (AlOₓ).

The third planarization layer 220 may be located on the capping layer CAP. The third planarization layer 220 is used for flattening the top surface of the display panel 100 (or the top surface of the light emitting element layer included in the display panel 100), and the top surface of the third planarization layer 220 may be substantially flat. In one or more embodiments, the third planarization layer 220 may be formed as an organic film including an organic material such as acrylic resin, epoxy resin, phenolic resin, polyamide resin, and/or polyimide resin, and thus may have a substantially flat surface. In another embodiment, the third planarization layer 220 may include an inorganic material, and may be formed as an inorganic film with a sufficient thickness and have a substantially flat surface, or may be flattened by a planarization process such as a polishing process or an etching process.

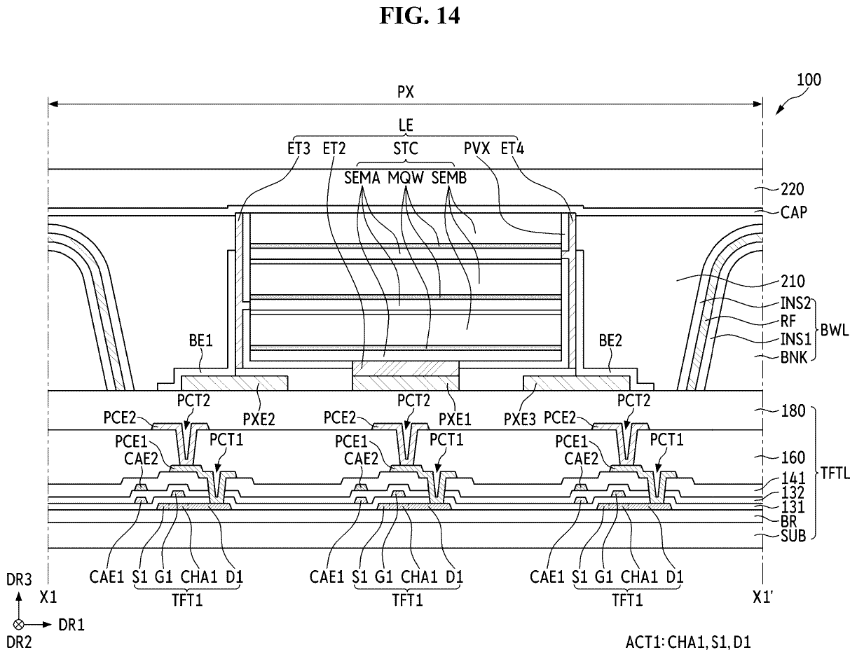

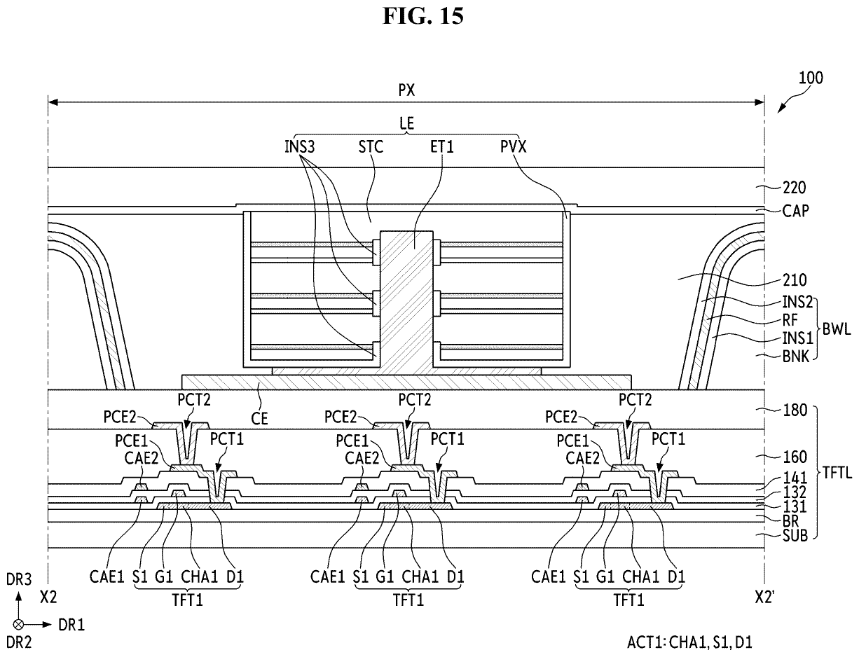

FIG. 14 is a cross-sectional view illustrating a display area of a display panel according to one or more embodiments. FIG. 15 is a cross-sectional view illustrating a display area of a display panel according to one or more embodiments. For example, FIGS. 14 and 15 show an example of the cross-section of the pixel PX corresponding to the lines X1-X1′ and X2-X2′ of FIG. 5, respectively.

In comparison with FIGS. 11 and 12, FIGS. 14 and 15 show another embodiment of the internal structure of the light emitting element LE. In describing the embodiments of the present disclosure, elements similar or identical to those of at least one embodiment described above are designated with the same reference numerals, and redundant descriptions will be omitted.

Referring to FIGS. 14 and 15 in addition to FIG. 11-13, the light emitting element LE may include the plurality of light emitting units EMU including the respective first conductivity type semiconductor layers SEMA, the respective active layers MQW, and the respective second conductivity type semiconductor layers SEMB as in the embodiment of FIG. 13. However, in each light emitting unit EMU, the stacking order of the first conductivity type semiconductor layer SEMA and the second conductivity type semiconductor layer SEMB may vary. For example, unlike the embodiment of FIG. 11-13, in the embodiment of FIGS. 14 and 15, the second conductivity type semiconductor layer SEMB having a thickness greater than the thickness of the first conductivity type semiconductor layer SEMA may be located on each active layer MQW, and the first conductivity type semiconductor layer SEMA may be located under each active layer MQW.

In the embodiments of FIGS. 14 and 15, the first conductivity type semiconductor layer SEMA (for example, the first semiconductor layer SEM1A of FIG. 13) of the first light emitting unit EMU1 may be located at the lowermost portion of the semiconductor stack STC, and the second electrode ET2 of the light emitting element LE may be in direct contact with the bottom surface of the first conductivity type semiconductor layer SEMA of the first light emitting unit EMU1. In one or more embodiments, the second electrode ET2 may not penetrate the semiconductor stack STC. The third electrode ET3 and the fourth electrode ET4 of the light emitting element LE may be in contact with the side surface of the semiconductor stack STC at positions corresponding to the first conductivity type semiconductor layers SEMA (for example, the third semiconductor layer SEM2A and the fifth semiconductor layer SEM3A of FIG. 13) of the second light emitting unit EMU2 and the third light emitting unit EMU3, respectively.

Although FIG. 11-13 and FIGS. 14 and 15 illustrate the embodiments in which the stacking order of the first conductivity type semiconductor layer SEMA, the active layer MQW, and the second conductivity type semiconductor layer SEMB is the same in each of the light emitting units EMU, the present disclosure is not limited thereto. The stacking order of the first conductivity type semiconductor layer SEMA, the active layer MQW, and the second conductivity type semiconductor layer SEMB included in the first light emitting unit EMU1 may be different from the stacking order of the first conductivity type semiconductor layer SEMA, the active layer MQW, and the second conductivity type semiconductor layer SEMB included in the second light emitting unit EMU2, and/or the stacking order of the first conductivity type semiconductor layer SEMA, the active layer MQW, and the second conductivity type semiconductor layer SEMB included in the third light emitting unit EMU3. In this case, the third electrode ET3 and the fourth electrode ET4 may be in contact with the side surface of the semiconductor stack STC at positions corresponding to the first conductivity type semiconductor layers SEMA of the second light emitting unit EMU2 and the third light emitting unit EMU3, respectively.

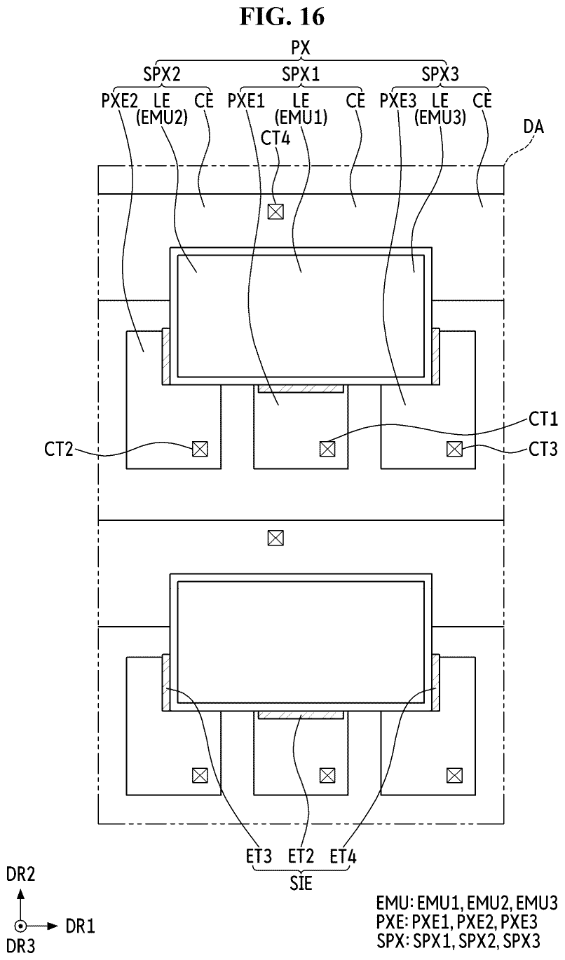

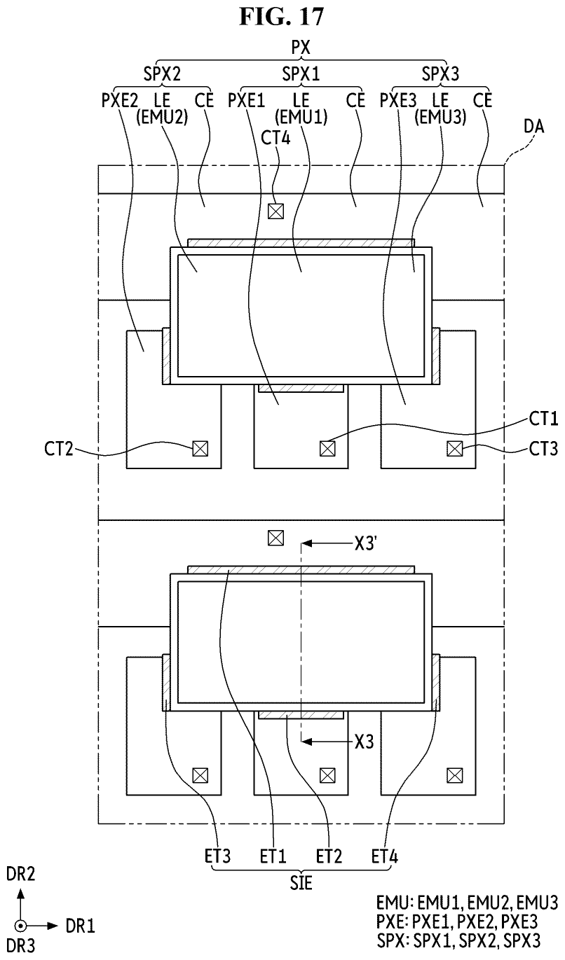

FIG. 16 is a plan view illustrating a display area of a display panel according to one or more embodiments. FIG. 17 is a plan view illustrating a display area of a display panel according to one or more embodiments. For example, FIGS. 16 and 17 show a part of the display area DA including two pixels PX sequentially arranged along the second direction DR2, and show embodiments that are different from the embodiment of FIG. 5 in relation to the light emitting element LE.

Referring to FIGS. 16 and 17, the light emitting element LE may include the side electrodes SIE that are separate from each other on the first pixel electrode PXE1, the second pixel electrode PXE2, and the third pixel electrode PXE3. For example, the second electrode ET2 of the light emitting element LE may be formed as the side electrode SIE located on one side surface of the light emitting element LE located on the first pixel electrode PXE1.

The light emitting element LE may include the bottom electrode BTE according to the embodiments of FIG. 5-15, or may not include the bottom electrode BTE.

In one or more embodiments, the light emitting element LE may include the side electrodes SIE located on the respective pixel electrodes PXE as illustrated in FIG. 16, and may further include the first electrode ET1 disclosed in the embodiments described above. For example, the light emitting element LE may further include the first electrode ET1 located on a part of the bottom surface BS of the light emitting element LE and bonded between the common electrodes CE (e.g., bonded with the common electrode CE).

In one or more embodiments, the light emitting element LE may further include the side electrode SIE located on the common electrode CE. For example, as illustrated in FIG. 17, the first electrode ET1 of the light emitting element LE may be formed as the side electrode SIE located on one side surface of the light emitting element LE located on the common electrode CE. For example, the light emitting element LE may include the first electrode ET1, the second electrode ET2, the third electrode ET3, and the fourth electrode ET4 that are located on different side surfaces and electrically connected to the pixel electrode PXE or common electrode CE.

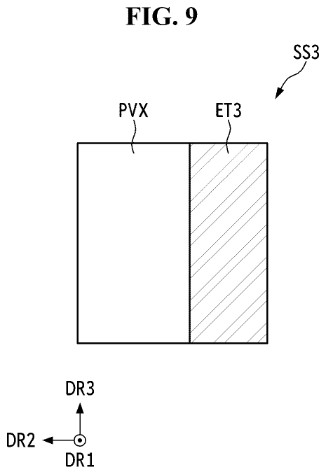

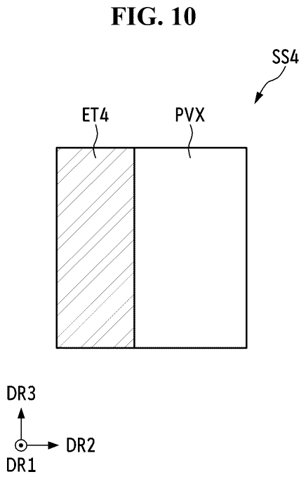

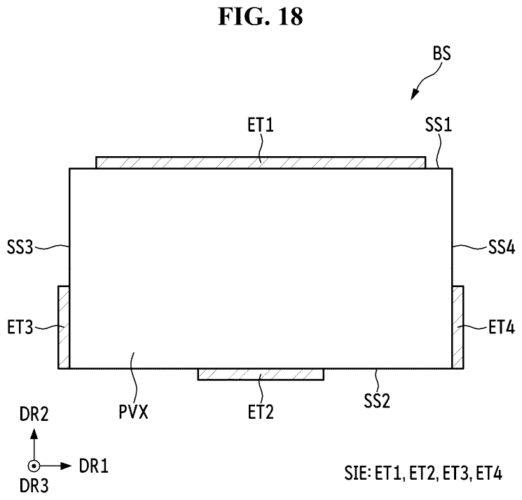

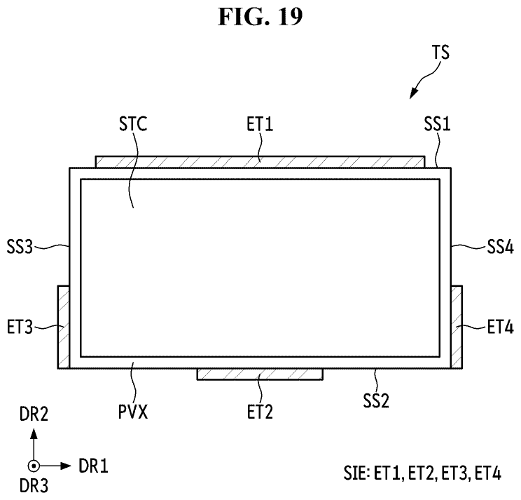

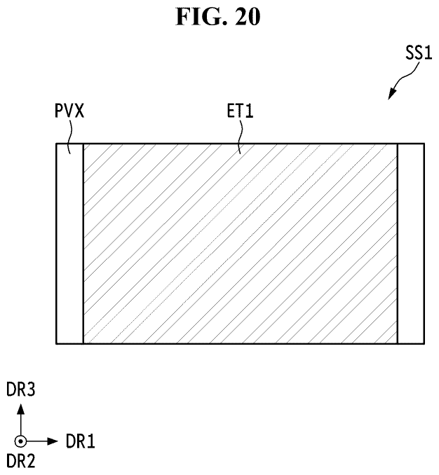

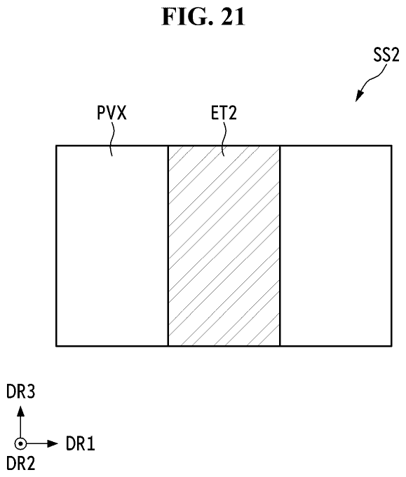

FIG. 18-21 are plan views showing a light emitting element according to one or more embodiments. For example, FIG. 18-21 show different side surfaces of the light emitting element LE illustrated in FIG. 17. For example, FIG. 18-21 show the bottom surface BS, the top surface TS, the first side surface SS1, and the second side surface SS2 of the light emitting element LE, respectively. The third side surface SS3 and the fourth side surface SS4 of the light emitting element LE may be the same as the third side surface SS3 and the fourth side surface SS4 of the light emitting element LE illustrated in FIGS. 9 and 10.

In comparison with FIG. 5-10, FIG. 18-21 show an embodiment in which the first electrode ET1, the second electrode ET2, the third electrode ET3, and the fourth electrode ET4 of the light emitting element LE are all formed as the side electrodes SIE.

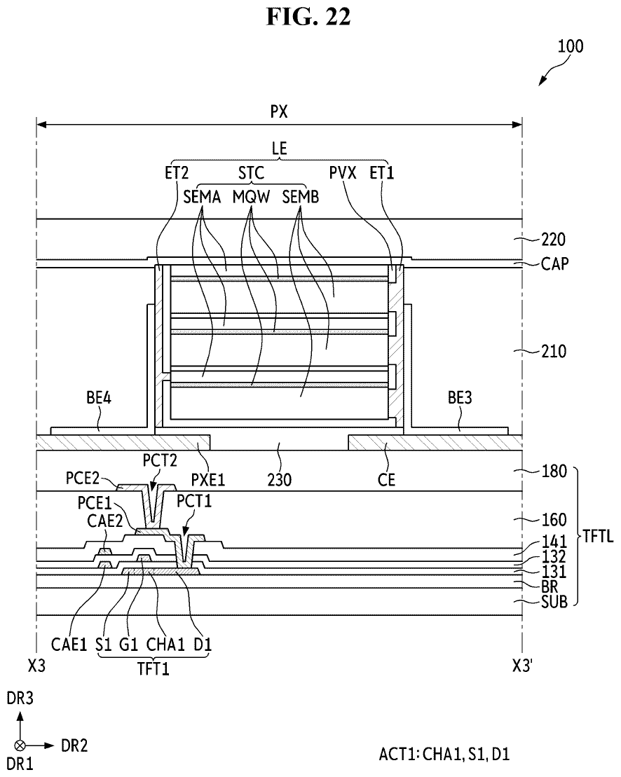

FIG. 22 is a cross-sectional view illustrating a display area of a display panel according to one or more embodiments. For example, FIG. 22 shows an example of the cross-section of the pixel PX corresponding to the line X3-X3′ of FIG. 17.

Referring to FIG. 18-22 in addition to FIG. 17, the light emitting element LE according to one or more embodiments may include the first electrode ET1 located on the first side surface SS1, the second electrode ET2 located on the second side surface SS2, the third electrode ET3 located on the third side surface SS3, and the fourth electrode ET4 located on the fourth side surface SS4. For example, the first electrode ET1, the second electrode ET2, the third electrode ET3, and the fourth electrode ET4 of the light emitting element LE may be formed as the side electrodes SIE that are located separately from each other on different side surfaces of the light emitting element LE.

As in the embodiments described above, the light emitting element LE may include the semiconductor stack STC including the first light emitting unit EMU1, the second light emitting unit EMU2, and the third light emitting unit EMU3. Each of the first light emitting unit EMU1, the second light emitting unit EMU2, and the third light emitting unit EMU3 may include the first conductivity type semiconductor layer SEMA, the active layer MQW, and the second conductivity type semiconductor layer SEMB.

The display panel 100 according to one or more embodiments may further include a third connection electrode BE3 and a fourth connection electrode BE4 that electrically connect the first electrode ET1 and the second electrode ET2 of the light emitting element LE to the common electrode CE and the first pixel electrode PXE1, respectively. The third electrode ET3 and the fourth electrode ET4 of the light emitting element LE may be electrically connected to the second pixel electrode PXE2 and the third pixel electrode PXE3 by the first connection electrode BE1 and the second connection electrode BE2, respectively, as in the embodiments of FIG. 5-15.

The first electrode ET1 of the light emitting element LE may be located on one side surface of the passivation film PVX overlapping the common electrode CE, and may be electrically connected to at least one semiconductor layer included in the semiconductor stack STC on the side surface of the semiconductor stack STC. For example, the first electrode ET1 of the light emitting element LE may be in contact with the respective side surfaces of the second conductivity type semiconductor layers SEMB included in the light emitting units EMU of the semiconductor stack STC while penetrating the passivation film PVX.

The second electrode ET2 of the light emitting element LE may be located on one side surface of the passivation film PVX overlapping the first pixel electrode PXE1, and may be electrically connected to at least one semiconductor layer included in the semiconductor stack STC on the side surface of the semiconductor stack STC. For example, the second electrode ET2 of the light emitting element LE may be in contact with the side surface of the first conductivity type semiconductor layer SEMA included in the first light emitting unit EMU1 of the semiconductor stack STC while penetrating the passivation film PVX.

The third connection electrode BE3 may be located on the common electrode CE and the first electrode ET1 and electrically connect the common electrode CE to the first electrode ET1. For example, the third connection electrode BE3 may be directly located on a part of the common electrode CE and the first electrode ET1 to be in contact with the common electrode CE and the first electrode ET1, and thus may be electrically connected to the common electrode CE and the first electrode ET1.

The fourth connection electrode BE4 may be located on the first pixel electrode PXE1 and the second electrode ET2 and electrically connect the first pixel electrode PXE1 to the second electrode ET2. For example, the fourth connection electrode BE4 may be directly located on a part of the first pixel electrode PXE1 and the second electrode ET2 to be in contact with the first pixel electrode PXE1 and the second electrode ET2, and thus may be electrically connected to the first pixel electrode PXE1 and the second electrode ET2.

Each of the third connection electrode BE3 and the fourth connection electrode BE4 may include a conductive material. For example, each of the first connection electrode BE1 and the second connection electrode BE2 may include molybdenum (Mo), aluminum (Al), chromium (Cr), gold (Au), titanium (Ti), nickel (Ni), neodymium (Nd), and/or copper (Cu), or a transparent conductive material such as indium-tin oxide (ITO) and/or indium-zinc oxide (IZO).

In one or more embodiments, the third connection electrode BE3 and the fourth connection electrode BE4 may include a metal having high reflectivity or a transparent conductive material mentioned above as the material of the first connection electrode BE1 and the second connection electrode BE2. For example, the first connection electrode BE1, the second connection electrode BE2, the third connection electrode BE3, and the fourth connection electrode BE4 may be formed concurrently (e.g., simultaneously) using the same conductive material.

The display panel 100 according to one or more embodiments may further include an adhesive layer 230 located under the light emitting element LE. The adhesive layer 230 may be located between the pixel electrode layer and the light emitting element LE, and may cover a part of each of the pixel electrodes PXE and the common electrode CE. The adhesive layer 230 may not cover another part of each of the pixel electrodes PXE and the common electrode CE.

The adhesive layer 230 serves to temporarily fix or adhere the light emitting element LE to prevent the light emitting element LE from tilting and falling over or tipping over during the process of transferring the light emitting element LE to the display panel 100. For example, the adhesive layer 230 may be a film for temporarily adhering the light emitting element LE onto the pixel electrodes PXE and the common electrode CE. In order to facilitate temporary adhesion, the thickness of the adhesive layer 230 may be greater than the thickness of each of the pixel electrodes PXE and the common electrode CE.

Although FIG. 22 illustrates a structure in which the adhesive layer 230 is located only in a part of each pixel area, the present disclosure is not limited thereto. For example, the adhesive layer 230 according to one or more other embodiment may be formed in the entire display area DA, and may be locally removed at portions corresponding to the connection holes for connecting the first connection electrode BE1, the second connection electrode BE2, the third connection electrode BE3, and the fourth connection electrode BE4 to the second pixel electrode PXE2, the third pixel electrode PXE3, the common electrode CE, and the first pixel electrode PXE1, respectively.

The adhesive layer 230 may include an organic insulating material. For example, the adhesive layer 230 may be formed as a photosensitive organic film including a photoresist. Alternatively, the adhesive layer 230 may be formed as an organic film including acryl resin, epoxy resin, phenolic resin, polyamide resin, polyimide resin, and/or the like. The light emitting element LE may be located on the adhesive layer 230.

Although FIG. 17-22 illustrate an embodiment in which the light emitting element LE does not include the bottom electrode BTE described in the embodiments of FIG. 5-15, the present disclosure is not limited thereto. In addition, each of the embodiments described in FIG. 5-22 may be implemented alone or in combination with at least one other embodiment.

For example, as in the embodiment of FIG. 17-22, the first conductivity type semiconductor layers SEMA and the second conductivity type semiconductor layers SEMB included in the semiconductor stack STC of the light emitting element LE may each be electrically connected to each pixel electrode PXE or the common electrode CE through the side electrode SIE electrically connected to the semiconductor stack STC on the side surface of the semiconductor stack STC. In addition, at least one of the first conductivity type semiconductor layers SEMA or the second conductivity type semiconductor layers SEMB included in the semiconductor stack STC of the light emitting element LE may be electrically connected to each pixel electrode PXE or the common electrode CE via the bottom electrode BTE located on the bottom surface of the semiconductor stack STC, as in the embodiment of FIGS. 5-15 . For example, the first electrode ET1 of the light emitting element LE may be formed as a multi-electrode including the bottom electrode BTE located on the bottom surface of the light emitting element LE and penetrating the semiconductor stack STC, and the side electrode SIE located on the side surface of the light emitting element LE to be in contact with the side surface of the semiconductor stack STC while penetrating the passivation film PVX.

As described above, the light emitting element LE according to one or more embodiments may include the semiconductor stack STC including the plurality of light emitting units EMU emitting light of different colors, the passivation film PVX located on the side surface of the semiconductor stack STC, and at least one side electrode SIE located on the side surface of the passivation film PVX and electrically connected to a part of the semiconductor stack STC on the side surface of the semiconductor stack STC. According to one or more embodiments, in the light emitting element LE having a 1-chip structure, the number of electrodes penetrating the semiconductor stack STC may be reduced or minimized, and the loss of the emission area of the semiconductor stack STC (or the loss of a volume of at least one active layer MQW included in the semiconductor stack STC) may be reduced or prevented. Accordingly, the luminous efficiency of the light emitting element LE may be improved.

In addition, the light emitting element LE according to one or more embodiments may include a reduced or minimized number of electrodes. According to one or more embodiments, the light emitting element LE may be more easily located and/or bonded inside the display device 1 or the electronic device 10 (for example, on the pixel electrode layer and/or the thin film transistor layer TFTL of the display panel 100). Accordingly, the efficiency of the bonding process for locating the light emitting element LE in each pixel PX may be increased. In addition, even if bonding failure of the light emitting element LE occurs, a repair process may be more easily performed.

The display device 1 according to one or more embodiments may include the light emitting element LE. According to one or more embodiments, the size of the pixel PX may be easily reduced by integrating the light emitting elements LE of the sub-pixels SPX into one light emitting element LE, and the luminous efficiency of the pixel PX may be improved by improving the luminous efficiency of the light emitting element LE. Accordingly, the high-resolution display device 1 may be easily manufactured, and the light efficiency of the display device may be improved.

In one or more embodiments, the light emitting element LE may further include the bottom electrode BTE located on the bottom surface BS of the semiconductor stack STC and electrically connected to another part of the semiconductor stack STC on and/or inside the bottom surface BS of the semiconductor stack STC. According to the light emitting element LE and the display device 1 including the same according to one or more embodiments, the light emitting element LE may be located more stably on the pixel electrode layer of the display device 1. Accordingly, the reliability of the display device 1 may be improved.

The display device 1 according to at least one of the above-described embodiments may be applied to various electronic devices. The electronic device according to one or more embodiments may include the above-described display device 1 (or a display module including the display panel 100 according to one or more embodiments), and may further include modules or devices having other additional functions in addition to the display device 1.

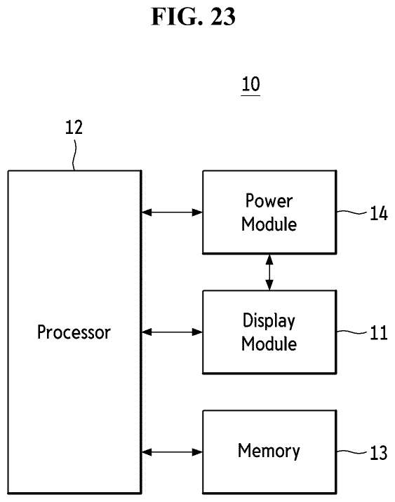

FIG. 23 is a block diagram of an electronic device according to one or more embodiments. Referring to FIG. 23, an electronic device 10 according to one or more embodiments may include a display module 11, a processor 12, a memory 13, and a power module 14.

The electronic device 10 may output various information in the form of images through the display module 11. For example, when the processor 12 executes an application stored in the memory 13, image information provided by the application may be provided to a user through the display module 11.

The display module 11 may include the display panel 100 for displaying an image. For example, the display module 11 may include the display panel 100 according to at least one of the aforementioned embodiments.

The processor 12 may include at least one of a central processing unit (CPU), an application processor (AP), a graphic processing unit (GPU), a communication processor (CP), an image signal processor (ISP), or a controller.

The memory 13 may store data information required for the operation of the processor 12 or the display module 11. For example, the memory 13 may store an image data signal and/or an input control signal.

The processor 12 may control the display module 11 using information stored in the memory 13. The processor 12 may transmit the image data signal and/or the input control signal stored in the memory 13 to the display module 11. For example, when the processor 12 executes an application stored in the memory 13, an image data signal and/or an input control signal is transmitted to the display module 11, and the display module 11 may process the received signal and output image information through a display screen.

The power module 14 may include a power supply module, such as a power adapter and/or a battery device, and a power conversion module that converts power supplied by the power supply module to generate power required for the operation of the electronic device 10.

At least one of the components of the electronic device 10 described above may be included in the display device 1 according to one or more embodiments described above. Further, some of individual modules functionally included in one module may be included in the display device 1 and some others may be provided separately from the display device 1. For example, the display device 1 may include the display module 11, and the processor 12, the memory 13, and the power module 14 may be provided in the form of other devices in the electronic device 10 other than the display device 1.

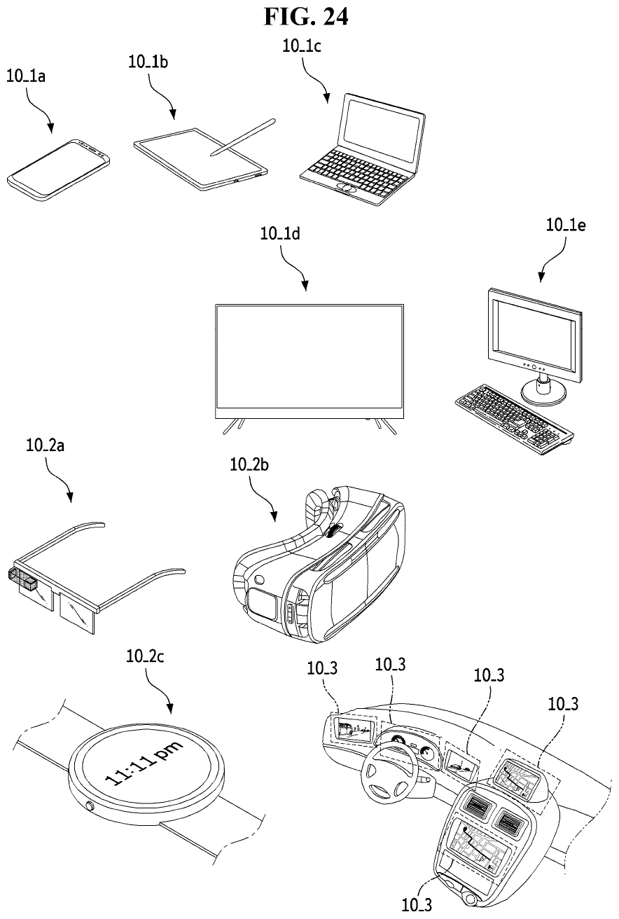

FIG. 24 is schematic views of electronic devices according to various embodiments.

Referring to FIG. 24, various electronic devices 10 (see FIG. 23) to which the display device 1 according to one or more embodiments is applied may include not only an image display electronic device such as a smartphone 10_1a, a tablet PC 10_1b, a laptop 10_1c, a TV 10_1d, and a desk monitor 10_1e, but also a wearable electronic device including a display module, such as smart glasses 10_2a, a head mounted display 10_2b, or a smart watch 10_2c, a vehicle electronic device 10_3 including a display module, such as a center fascia, and a dashboard of an automobile, a center information display (CID) placed on the dashboard, a room mirror display, and the like.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a substrate;
pixel electrodes and a common electrode located on the substrate; and
a light emitting element located on the pixel electrodes and the common electrode,
wherein the light emitting element comprises:
a semiconductor stack having a structure in which light emitting units configured to emit light of different colors are stacked;
a passivation film located on a side surface of the semiconductor stack; and
at least one side electrode located on a side surface of the passivation film and electrically connected to the semiconductor stack on the side surface of the semiconductor stack.

2. The display device of claim 1, wherein the light emitting element further comprises at least one bottom electrode located on a bottom surface of the semiconductor stack and electrically connected to the semiconductor stack.

3. The display device of claim 2, wherein each of the light emitting units comprises an active layer, and a first conductivity type semiconductor layer and a second conductivity type semiconductor layer located on different surfaces of the active layer, and
wherein the at least one bottom electrode comprises a first electrode located on a part of the bottom surface of the semiconductor stack and electrically connected to second conductivity type semiconductor layers of the light emitting units, wherein the first electrode penetrates a part of the semiconductor stack.

4. The display device of claim 3, wherein the first electrode is bonded onto the common electrode.

5. The display device of claim 3, wherein the at least one bottom electrode further comprises a second electrode located on another part of the bottom surface of the semiconductor stack and electrically connected to the first conductivity type semiconductor layer of one of the light emitting units.

6. The display device of claim 5, wherein the second electrode is bonded onto one of the pixel electrodes.

7. The display device of claim 1, wherein each of the light emitting units comprises an active layer, and a first conductivity type semiconductor layer and a second conductivity type semiconductor layer located on different surfaces of the active layer, and
wherein the at least one side electrode comprises a third electrode located on a part of the side surface of the semiconductor stack and in contact with a side surface of the first conductivity type semiconductor layer of one of the light emitting units, wherein the third electrode penetrates the passivation film.

8. The display device of claim 7, wherein the third electrode is located on one of the pixel electrodes.

9. The display device of claim 8, further comprising a connection electrode located on the third electrode and the one of the pixel electrodes, the connection electrode electrically connecting the third electrode to the one of the pixel electrodes.

10. The display device of claim 1, wherein the at least one side electrode comprises a transparent conductive material.

11. The display device of claim 1, wherein the light emitting units comprise:
a first light emitting unit comprising a first active layer configured to emit light of a first color, and a first semiconductor layer and a second semiconductor layer located on different surfaces of the first active layer;
a second light emitting unit comprising a second active layer configured to emit light of a second color, and a third semiconductor layer and a fourth semiconductor layer located on different surfaces of the second active layer; and
a third light emitting unit comprising a third active layer configured to emit light of a third color, and a fifth semiconductor layer and a sixth semiconductor layer located on different surfaces of the third active layer.

12. The display device of claim 11, wherein the pixel electrodes comprise a first pixel electrode electrically connected to the first light emitting unit, a second pixel electrode electrically connected to the second light emitting unit, and a third pixel electrode electrically connected to the third light emitting unit, and
wherein the light emitting element comprises a first electrode electrically connected to the common electrode, a second electrode electrically connected to the first pixel electrode, a third electrode electrically connected to the second pixel electrode, and a fourth electrode electrically connected to the third pixel electrode.

13. The display device of claim 12, wherein the at least one side electrode comprises the third electrode and the fourth electrode,
wherein the third electrode is located on one side surface of the passivation film overlapping the second pixel electrode, and is in contact with a side surface of the third semiconductor layer, wherein the third electrode penetrates the passivation film, and
wherein the fourth electrode is located on one side surface of the passivation film overlapping the third pixel electrode, and is in contact with a side surface of the fifth semiconductor layer, wherein the fourth electrode penetrates the passivation film.

14. The display device of claim 13, further comprising:
a first connection electrode located on the third electrode and the second pixel electrode, and electrically connecting the third electrode to the second pixel electrode; and
a second connection electrode located on the fourth electrode and the third pixel electrode, and electrically connecting the fourth electrode to the third pixel electrode.

15. The display device of claim 13, wherein the at least one side electrode further comprises at least one of the first electrode or the second electrode, and
wherein the display device further comprising at least one of a third connection electrode electrically connecting the first electrode to the common electrode, or a fourth connection electrode electrically connecting the second electrode to the first pixel electrode.

16. The display device of claim 15, wherein the first electrode is located on one side surface of the passivation film overlapping the common electrode, and is in contact with a side surface of each of the second semiconductor layer, the fourth semiconductor layer, and the sixth semiconductor layer, wherein the first electrode penetrates the passivation film, and
wherein the second electrode is located on one side surface of the passivation film overlapping the first pixel electrode, and is in contact with a side surface of the first semiconductor layer, wherein the second electrode penetrates the passivation film.

17. The display device of claim 12, wherein the light emitting element further comprises at least one bottom electrode located on a bottom surface of the semiconductor stack, and
wherein the at least one bottom electrode comprises at least one of the first electrode or the second electrode.

18. The display device of claim 17, wherein the first electrode is located on a part of the bottom surface of the semiconductor stack and a top surface of the common electrode and bonded to the common electrode, wherein the first electrode is electrically connected to the second semiconductor layer, the fourth semiconductor layer, and the sixth semiconductor layer and penetrates a part of the semiconductor stack, and
wherein the second electrode is located on another part of the bottom surface of the semiconductor stack and a top surface of the first pixel electrode and bonded to the first pixel electrode, the second electrode being electrically connected to the first semiconductor layer.

19. An electronic device comprising:
a display module comprising a display panel; and
a processor configured to transmit an image data signal to the display module,
wherein the display panel comprises:
a substrate;
pixel electrodes and a common electrode located on the substrate;
a light emitting element located on the pixel electrodes and the common electrode, the light emitting element comprising a semiconductor stack having a structure in which light emitting units configured to emit light of different colors are stacked, a passivation film located on a side surface of the semiconductor stack, and a side electrode located on a side surface of the passivation film and electrically connected to the semiconductor stack on the side surface of the semiconductor stack; and
a connection electrode located on one of the pixel electrodes or the common electrode and the side electrode and electrically connecting the one of the pixel electrodes or the common electrode to the side electrode.

20. The electronic device of claim 19, wherein the light emitting element further comprises a bottom electrode located on a bottom surface of the semiconductor stack and electrically connected to the semiconductor stack, and
wherein the bottom electrode is bonded onto another one of the pixel electrodes or the common electrode.
